(19) United States
(12) Patent Application Publication
(10) Pub. No.: US 2025/0359021 A1
(43) Pub. Date: Nov. 20, 2025

(54) SEMICONDUCTOR DYNAMIC RANDOM-ACCESS MEMORY DEVICES

(71) Applicant: Samsung Electronics Co., Ltd., Suwon-si (KR)

(72) Inventors: Taemin Cha, Suwon-si (KR); Moonyoung Jeong, Suwon-si (KR)

(21) Appl. No.: 19/051,658

(22) Filed: Feb. 12, 2025

(30) Foreign Application Priority Data
May 20, 2024 (KR) 10-2024-0065149

(51) Int. Cl. H10B 12/00

(52) U.S. Cl. CPC H10B 12/315; H10B 12/033; H10B 12/05; H10B 12/50

(57) ABSTRACT

A semiconductor device includes a transistor including a first gate structure on a first substrate including a first semiconductor material, and a first channel at a portion of the first substrate extending below the first gate structure; a bit line structure on the transistor and in a first direction substantially parallel to an upper surface of the first substrate; a second channel including a second semiconductor material having a different crystal orientation relative to the first semiconductor material, said second channel extending on the bit line structure and in a vertical direction substantially perpendicular to the upper surface of the first substrate; a second gate structure at a first sidewall in the first direction of the second channel and extending in a second direction, which is substantially parallel to the upper surface of the first; and a capacitor on and electrically connected to the second channel.

### CROSS-REFERENCE TO RELATED APPLICATION

This application claims priority under 35 U.S.C. § 119 to Korean Patent Application No. 10-2024-0065149 filed on May 20, 2024, the disclosure of which is hereby incorporated by reference in its entirety.

### TECHNICAL FIELD

Example embodiments of the present disclosure relate to a semiconductor device. More particularly, example embodiments of the present disclosure relate to a DRAM device.

### BACKGROUND

Depending on the crystal plane of a single crystal silicon, density of surface defects, reliability, threshold voltage, etc. of a transistor may vary. For example, {100} crystal plane of a single crystal silicon may have a low atomic surface density, resulting in a fast thermal oxidation rate and a fast etching rate.

A cell transistor and a core/peri transistor may be formed on the same silicon wafer. However, important characteristics such as the reliability of the cell transistor or the fast signal transmission of the core/peri transistor may be difficult to optimize.

### SUMMARY

Example embodiments provide a first semiconductor device having improved characteristics.

Example embodiments provide a second semiconductor device having improved characteristics.

Example embodiments provide a third semiconductor device having improved characteristics.

According to example embodiments, there is provided a semiconductor device. The semiconductor device may include a transistor including a first gate structure on a first substrate including a first semiconductor material, and a first channel at a portion of the first substrate extending below the first gate structure; a bit line structure that extends on the transistor in a first direction substantially parallel to an upper surface of the first substrate; a second channel including a second semiconductor material, said second channel extending on the bit line structure and in a vertical direction substantially perpendicular to the upper surface of the first substrate; a second gate structure at a first sidewall in the first direction of the second channel and extending in a second direction, which is substantially parallel to the upper surface of the first substrate and substantially perpendicular to the first direction; and a capacitor on and electrically connected to the second channel.

According to example embodiments, there is provided a semiconductor device. The semiconductor device may include a first transistor on a first substrate including a first semiconductor material; a bonding layer on the first substrate and the first transistor; a second transistor on the bonding layer, the second transistor comprising a vertical channel including a second semiconductor material said vertical channel extending in a vertical direction substantially perpendicular to an upper surface of the first substrate, and a first gate structure at a first sidewall in a first direction of the vertical channel and extending in a second direction, each of the first and second direction substantially parallel to the upper surface of the first substrate, the first and second direction being substantially perpendicular to each other; a bit line structure electrically connected to the vertical channel and positioned at a first end of the vertical channel and extending in the first direction; a capacitor electrically connected to the vertical channel, the capacitor at a second end of the vertical channel, the second end of the vertical channel facing the first end of the vertical channel, and wherein the second semiconductor material comprises single crystal silicon, and a {100} crystal plane of the second semiconductor material is substantially perpendicular to the first direction, and wherein the first semiconductor material includes single crystal silicon-germanium, and a {110} crystal plane of the first semiconductor material is substantially perpendicular to a direction of a current flowing in a channel of the first transistor.

According to example embodiments, there is provided a semiconductor device. The semiconductor device may include an active pattern on a first substrate including a first semiconductor material; a gate structure extending in a first direction substantially parallel to an upper surface of the first substrate through an upper portion of the active pattern; a bit line structure in contact with a central portion of an upper surface of the active pattern and extending in a second direction, the second direction substantially parallel to the upper surface of the first substrate and substantially perpendicular to the first direction; a contact plug structure in contact with each opposite edge portions of the upper surface of the active pattern; a capacitor on the contact plug structure; second substrate on the capacitor and including a second semiconductor; and a transistor below the second substrate, and wherein the first and second semiconductor materials have different crystal orientations

In a method of manufacturing the semiconductor device in accordance with example embodiments, the cell transistor and the core/peri transistor may be formed on separate wafers. The cell transistor may be formed on a wafer having a crystal orientation that minimizes interface trap density, and the core/peri transistor may be formed on a wafer having a crystal orientation that maximizes electron mobility. Accordingly, characteristics of the semiconductor device may be improved.

### BRIEF DESCRIPTION OF THE DRAWINGS

FIG. 1 is a cross-sectional view illustrating a first semiconductor device in accordance with example embodiments.

FIGS. 2 to 15 are plan views and cross-sectional views illustrating a method of manufacturing a first semiconductor device in accordance with example embodiments.

FIG. 16 is a cross-sectional view illustrating a second semiconductor device in accordance with example embodiments.

FIGS. 17 and 18 are cross-sectional views illustrating a method of manufacturing a second semiconductor device in accordance with example embodiments.

FIGS. 19 and 20 are cross-sectional views illustrating a third semiconductor device in accordance with example embodiments.

FIGS. 21 to 64 are plan views and cross-sectional views illustrating a method of manufacturing a third semiconductor device in accordance with example embodiments.

### DETAILED DESCRIPTION

Hereinafter, in the specification (and not necessarily in the claims), two directions that are substantially perpendicular to each other among horizontal directions, which are substantially parallel to an upper surface of each of first to third substrates of the first and second semiconductor devices, may be referred to as first and second directions D1 and D2, respectively, and a vertical direction substantially perpendicular to the upper surface of the each of first to third substrates of the first and second semiconductor devices may be referred to as a third direction D3. In example embodiments, the first and second directions D1 and D2 may be orthogonal to each other.

Each of the first to third directions D1, D2 and D3 may represent not only a direction shown in the drawing, but also a reverse direction to the direction. It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the embodiment in use or operation in addition to the orientation depicted in the figures. For example, if the embodiment in the figures is turned over, elements described as “below” or “beneath” other elements or features would then be oriented “above” the other elements or features. Thus, the term “below” can encompass both an orientation of above and below. The embodiment may be otherwise oriented (rotated 90 degrees or at other orientations), and the spatially relative descriptors used herein may be interpreted accordingly.

When components or layers are referred to herein as “directly” on, or “in direct contact” or “directly connected,” no intervening components or layers are present. When a first component or layer are referred to herein as “on” a second component or layer, it will be understood that the first component or layer exists in a positive axial direction with respect to the second component or layer, with intervening components or layers potentially in between. Conversely, when components are “immediately” adjacent to one another, no intervening components may be present.

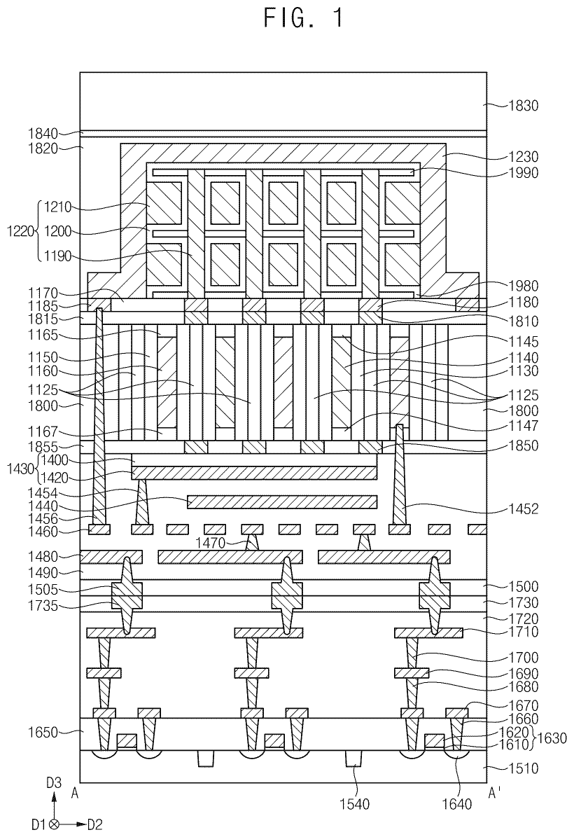

FIG. 1 is a cross-sectional view illustrating a first semiconductor device in accordance with example embodiments.

Referring to FIG. 1, the first semiconductor device may include a peripheral circuit region having a core/peri transistor and a cell array region having a cell transistor.

The first semiconductor device may have a cell over periphery (COP) structure, where the cell array region is formed over the peripheral circuit region. However, the concept of the present invention is not limited thereto, and the first semiconductor device of

FIG. 1 may have a periphery over cell (POC) structure, where the peripheral circuit region is formed over the cell array region.

The first semiconductor device may include a third gate structure 1630, a first impurity region 1640, a first wiring structure, a first bit line structure 1430, first and second gate structures, a first channel 1125, first and second semiconductor patterns 1810 and 1850, first and second pads 1180 and 1185, a first capacitor 1220 and a first plate electrode 1230.

The first semiconductor device may further include a first isolation pattern 1540, first to eighth insulating interlayers 1800, 1815, 1170, 1820, 1855, 1490, 1650 and 1720, first to third bonding layers 1840, 1500, 1730, and first and second bonding structures 1505 and 1735.

The third substrate 1510 may include a semiconductor material, e.g., single crystal silicon, single crystal germanium, single crystal silicon-germanium, etc.

In example embodiments, considering characteristics of the core/peri transistor, {110} crystal plane, {320} crystal plane, {310} crystal plane, {100} crystal plane, etc., of the third substrate 1510 may be arranged to be substantially perpendicular to a direction of the current (that is, the second direction D2) flowing in a second channel, which is a portion of the third substrate 1510 below the third gate structure 1630.

In an example embodiment, when the third substrate 1510 includes silicon, considering mobility characteristics of electrons, {100} crystal plane may be arranged to be substantially perpendicular to the second direction D2, that is, the direction of the current flowing in the second channel. In an example embodiment, when the third substrate 1510 includes silicon-germanium, considering mobility characteristics of electrons, {110} crystal plane may be arranged to be substantially perpendicular to the second direction D2, that is, the direction of the current flowing in the second channel.

{110} crystal plane, {320} crystal plane, {310} crystal plane and {100} crystal plane may respectively include all crystal planes crystallographically equivalent to the (110) plane, (320) plane, (310) plane and (100) plane.

The first isolation pattern 1540 may be formed on an upper portion of the third substrate 1510. The first isolation pattern 1540 may include an oxide, e.g., silicon oxide.

The third gate structure 1630 may be formed on the third substrate 1510 and include a third gate insulation pattern 1610 and a third gate electrode 1620 sequentially stacked in the third direction D3. The first impurity region 1640 may be formed at an upper portion of the third substrate 1510 adjacent to the third gate structure 1630. The third gate structure 1630 and the first impurity region 1640 may collectively form the core/peri transistor.

The third gate electrode 1620 may include a conductive material, e.g., a metal, a metal nitride, a metal silicide, polysilicon doped with impurities, etc. The third gate insulation pattern 1610 may include an oxide, e.g., silicon oxide. The first impurity region 1640 may include, e.g., n-type impurities or p-type impurities.

The core/peri transistor may form a peripheral circuit pattern. The peripheral circuit pattern may be a circuit pattern of a bit line sense amplifier (BLSA), sub-word line driver (SWD), column decoder, column select line (CSL) driver, input/output sense amplifier (I/O SA), write driver, etc.

The seventh and eighth insulating interlayers 1650 and 1720 may be sequentially formed on the third substrate 1510. Each of the seventh and eighth insulating interlayers 1650 and 1720 may include an oxide, e.g., silicon oxide, or a low dielectric material.

The fourth contact plug 1660 may extend through the seventh insulating interlayer 1650 to contact an upper surface of the first impurity region 1640. The fourth to sixth wirings 1670, 1690 and 1710 may be sequentially stacked in the third direction D3. The fifth contact plug 1680 may extend through a portion of the eighth insulating interlayer 1720 to contact an upper surface of the fourth wiring 1670 and a lower surface of the fifth wiring 1690, and the second via 1700 may extend through a portion of the eighth insulating interlayer 1720 to contact an upper surface of the fifth wiring 1690 and a lower surface of the sixth wiring 1710.

In the drawing, the fourth to sixth wirings 1670, 1690 and 1710 are sequentially stacked in three layers in the third direction D3 within the eighth insulating interlayer 1720. However, the concept of the present invention is not limited thereto.

Each of the fourth to sixth wirings 1670, 1690 and 1710, the fourth and fifth contact plugs 1660 and 1680 and the second via 1700 may include, e.g., a metal, a metal nitride, a metal silicide, etc.

The third bonding layer 1730 may be formed on the eighth insulating interlayer 1720, and the second bonding structure 1735 may extend through the third bonding layer 1730 and an upper portion of the eighth insulating interlayer 1720.

In example embodiments, the second bonding structure 1735 may include a second bonding contact pattern extending through a lower portion of the third bonding layer 1730 and the upper portion of the eighth insulating interlayer 1720 to contact an upper surface of the sixth wiring 1710, and a second bonding pad extending through an upper portion of the third bonding layer 1730 to contact an upper surface of the second bonding contact pattern. A width in the horizontal direction of the second bonding contact pattern may increase in the third direction D3 away from the upper surface of the third substrate 1510, and a width in the horizontal direction of the upper surface of the second bonding contact pattern may be smaller than a width in the horizontal direction of a lower surface of the second bonding pad.

In example embodiments, a plurality of second bonding structures 1735 may be spaced apart from each other in the first and second directions D1 and D2.

The second bonding layer 1500 may be bonded to an upper surface of the third bonding layer 1730, and the first bonding structure 1505 may extend through a lower portion of the sixth insulating interlayer 1490 and the second bonding layer 1500.

In example embodiments, the first bonding structure 1505 may include a first bonding pad extending through a lower portion of the second bonding layer 1500 to contact an upper surface of the second bonding pad, and a first bonding contact pattern extending through the lower portion of the sixth insulating interlayer 1490 and an upper portion of the second bonding layer 1500 to contact an upper surface of the first bonding pad. A width in the horizontal direction of the first bonding contact pattern may decrease in the third direction D3 away from the upper surface of the third substrate 1510, and a width in the horizontal direction of a lower surface of the first bonding contact pattern may be smaller than a width in the horizontal direction of the upper surface of the first bonding pad.

In example embodiments, corresponding to the second bonding structures 1735, a plurality of first bonding structures 1505 may be spaced apart from each other in the first and second directions D1 and D2.

Each of the second and third bonding layers 1500 and 1730 may include, for example, silicon carbonitride, silicon oxide, etc. Each of the first and second bonding structures 1505 and 1735 may include a metal, for example, copper (Cu).

The sixth, fifth, first, second and third insulating interlayers 1490, 1855, 1800, 1815 and 1170 may be sequentially stacked on the second bonding layer 1500 and the first bonding structure 1505 in the third direction D3. Each of the sixth, fifth, first, second and third insulating interlayer 1490, 1855, 1800, 1815 and 1170 may include an oxide, e.g., silicon oxide, or a low dielectric material.

The third, second and first wirings 1480, 1460 and 1440 may be sequentially stacked in the third direction D3. The first via 1470 may partially extend through the sixth insulating interlayer 1490 to contact an upper surface of the third wiring 1480 and a lower surface of the second wiring 1460. The first contact plug 1452 may extend through an upper portion of the sixth insulating interlayer 1490, the fifth insulating interlayer 1855 and the fourth gate mask 1167 to contact an upper surface of the second wiring 1460 and a lower surface of the second gate electrode 1160. The second contact plug 1454 may extend through a portion of the sixth insulating interlayer 1490 to contact an upper surface of the second wiring 1460 and a lower surface of the first bit line structure 1430. The third contact plug 1456 may extend through an upper portion of the sixth insulating interlayer 1490, the fifth, first and second insulating interlayers 1855, 1800 and 1815 to contact an upper surface of the second wiring 1460 and a lower surface of the second pad 1185.

The first bit line structure 1430 may extend in the second direction D2 through an upper portion of the sixth insulating interlayer 1490, and a plurality of first bit line structures 1430 may be spaced apart from each other in the first direction D1.

In example embodiments, each of the first bit line structures 1430 may include first and second conductive patterns 1400 and 1420 sequentially stacked in the third direction D3. The first conductive patterns 1400 may include, for example, polysilicon doped with impurities, and the second conductive patterns 1420 may include, for example a metal.

The second semiconductor pattern 1850 may extend through the fifth insulating interlayer 1855 to contact an upper surface of the first bit line structure 1430. A plurality of second semiconductor patterns 1850 may be spaced apart from each other in the second direction D2 on each of the first bit line structures 1430. Accordingly, the second semiconductor patterns 1850 may be spaced apart from each other along the first and second directions D1 and D2. The second semiconductor pattern 1850 may include, for example, silicon doped with impurities. In example embodiments, the second semiconductor pattern 1850 may serve as a drain of a cell transistor that includes the first channel 1125 and the first gate structure.

The first gate structure may include a third gate mask 1147, a first gate electrode 1140 and a first gate mask 1145 sequentially stacked on the fifth insulating interlayer 1855, and a first gate insulation pattern 1130 at sidewalls in the second direction D2 of the third gate mask 1147, the first gate electrode 1140 and the first gate mask 1145. The second gate structure may include a fourth gate mask 1167, a second gate electrode 1160 and a second gate mask 1165 sequentially stacked on the fifth insulating interlayer 1855, and a second gate insulation pattern 1150 at sidewalls in the second direction D2 of the fourth gate mask 1167, the second gate electrode 1160 and the second gate mask 1165. In example embodiments, the first and second gate structures may be alternately and repeatedly arranged along the second direction D2.

In example embodiments, the first gate electrode 1140 may have a straight line shape extending in the first direction D1 in a plan view, while the second gate electrode 1160 may include an extension portion extending in the first direction D1 and protrusion portions protruding in the second direction D2 from each of opposite sidewalls in the second direction D2.

In example embodiments, the second gate electrode 1160 may serve as a word line of the first semiconductor device, and the first gate electrode 1140 may serve as a back gate electrode of the first semiconductor device.

In example embodiments, the first gate insulation pattern 1130 may have a straight line shape extending in the first direction D1, while the second gate insulation pattern 1150 may extend in a zigzag pattern in the first direction D1.

Each of the first and second gate electrodes 1140 and 1160 may include a metal, e.g., tungsten, copper, aluminum, etc. Each of the first and second gate insulation patterns 1130 and 1150 may include an oxide, e.g., silicon oxide.

The first channel 1125 may be formed on the second semiconductor pattern 1850 at a sidewall in the second direction D2 of the first gate insulation pattern 1130, and a plurality of first channels 1125 may be spaced apart from each other in the first and second directions D1 and D2. A first sidewall in the second direction D2 of the first channel 1125 may contact the first gate insulation pattern 1130, and a second sidewall in the second direction D2 and opposite sidewalls in the first direction D1 of the first channel 1125 may contact the second gate insulation pattern 1150.

The first channel 1125 may include a semiconductor material, e.g., single crystal silicon, single crystal germanium, single crystal silicon-germanium, etc.

In example embodiments, the first channel 1125 may have a different crystal orientation from the third substrate 1510.

In example embodiments, considering characteristics of the cell transistor, {100} crystal plane, {320} crystal plane, {310} crystal plane, {110} crystal plane, etc., of the first channel 1125 may be arranged to be substantially parallel to a first interface of the first channel 1125 and the second gate insulation pattern 1150 in the first direction D1, and a second interface between the first channel 1125 and the second gate insulation pattern 1150 in the second direction D2.

In an example embodiment, when the first channel 1125 includes silicon, considering interface trap density (DIT), {100} crystal plane of the first channel 1125 may be arranged to be substantially parallel to the first and second interfaces of the first channel 1125.

The first semiconductor pattern 1810 may extend through the second insulating interlayer 1815 to contact an upper surface of a corresponding one of the first channels 1125. Accordingly, a plurality of first semiconductor patterns 1810 may be spaced apart from each other in the first and second directions D1 and D2. The first semiconductor pattern 1810 may include, for example, silicon doped with impurities. In example embodiments, the first semiconductor pattern 1810 may serve as a source of the cell transistor.

The first pad 1180 may extend through the first insulating interlayer 1170 to contact a corresponding one of the first semiconductor patterns 1810. Accordingly, a plurality of first pads 1180 may be spaced apart from each other in the first and second directions D1 and D2. In example embodiments, the first pad 1180 may be arranged in a grid pattern or a honeycomb pattern in a plan view. The second pad 1185 may extend through the first insulating interlayer 1170 to contact the third contact plug 1456.

Each of the first and second pads 1180 and 1185 may include, for example, a metal, a metal nitride, a metal silicide, etc.

The first capacitor 1220 and the first plate electrode 1230 may be formed on the first insulating interlayer 1170 and the first and second pads 1180 and 1185, and may be covered by the fourth insulating interlayer 1820. The first capacitor 1220 may include a first capacitor electrode 1190, a first dielectric layer 1200 and a second capacitor electrode 1210 sequentially stacked.

The first capacitor electrode 1190 may extend in the third direction D3 to contact an upper surface of the first pad 1180. Accordingly, a plurality of first capacitor electrodes 1190 may be spaced apart from each other in the first and second directions D1 and D2. In example embodiments, the first capacitor electrodes 1190 may be arranged in a grid pattern or a honeycomb pattern in a plan view. The first pad 1180 may serve as a landing pad for the first capacitor electrode 1190.

A first etch stop layer 1980 and a support layer 1990 may be formed at a sidewall of each of the first capacitor electrodes 1190. The first etch stop layer 1980 may be formed at a lowermost sidewall of each of the first capacitor electrodes 1190, and a plurality of support layers 1990 may be spaced apart from each other in the third direction D3 along the sidewall of each of the first capacitor electrodes 1190.

The first dielectric layer 1200 may be formed at the sidewall of the first capacitor electrode 1190, upper and lower surfaces and a sidewall of the support layer 1990, and an upper surface and a sidewall of the first etch stop layer 1980. The second capacitor electrode 1210 may be formed between the support layers 1990 adjacent to each other in the third direction D3, and between a lowermost one of the support layers 1990 and the first etch stop layer 1980. Upper and lower surfaces and a sidewall of the second capacitor electrode 1210 may be covered by the first dielectric layer 1200.

The first plate electrode 1230 may cover upper surfaces and sidewalls of the first capacitor 1220, the support layer 1990, and the first etch stop layer 1980.

Each of the first and second capacitor electrodes 1190 and 1210 may include, e.g., a metal, a metal nitride, a metal silicide, etc., and the first dielectric layer 1200 may include, e.g., a metal oxide. The support layer 1990 may include an insulating nitride, e.g., silicon nitride, and the first etch stop layer 1980 may include an insulating nitride, e.g., silicon boronitride. The first plate electrode 1230 may include a metal, e.g., tungsten, or silicon-germanium doped or undoped with impurities. The fourth insulating interlayer 1820 may include an oxide, e.g., silicon oxide or a low dielectric material.

The first bonding layer 1840 may be bonded to an upper surface of the fourth insulating interlayer 1820 and may include, e.g., silicon carbonitride, silicon oxide, etc. The second substrate 1830 may be bonded to an upper surface of the first bonding layer 1840 and may include a semiconductor material, e.g., silicon or an insulating material, e.g., glass.

As described below, the first semiconductor device may be manufactured by forming the cell transistor and the core/peri transistor on separate wafers, and then bonding the separate wafers to each other. Crystal orientation of the first channel 1125 and crystal orientation of the third substrate 1510 may be adjusted in consideration of characteristics of each of the cell transistor and the core/peri transistor, and thus, the electrical characteristics of the first semiconductor device may be improved.

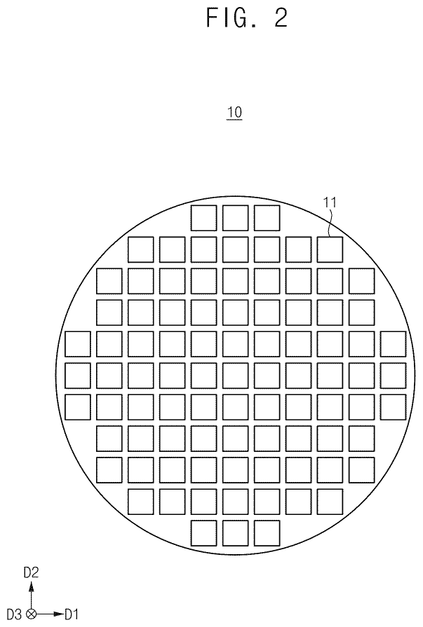

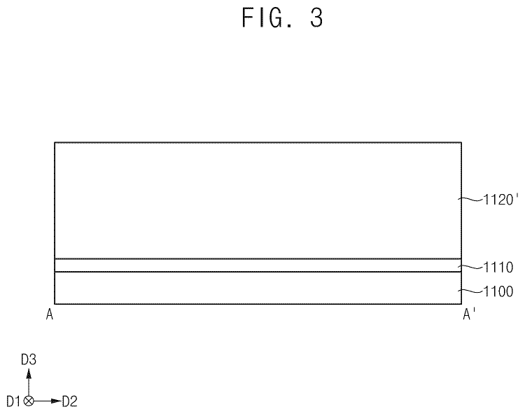

FIGS. 2 to 15 are plan views and cross-sectional views illustrating a method of manufacturing a first semiconductor device in accordance with example embodiments. Specifically, FIGS. 2, 4, 6, 9 and 14 are the plan views, and FIGS. 3, 5, 7-8, 10-13 and 15 are cross-sectional views taken along lines A-A′ of corresponding plan views, respectively.

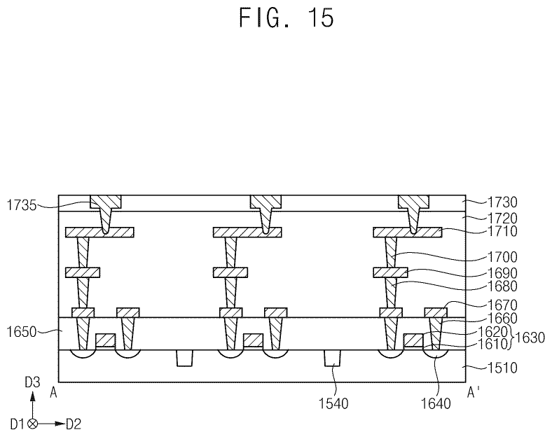

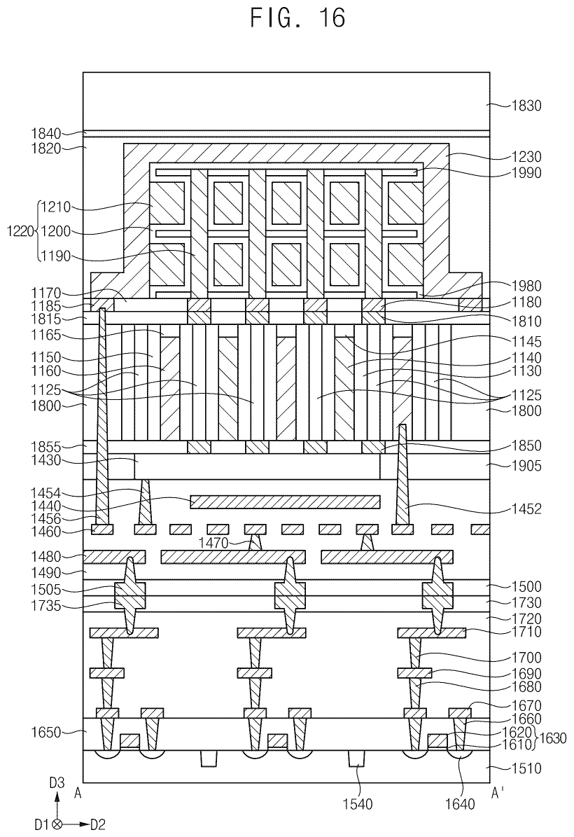

FIGS. 2 to 13 illustrate a method of manufacturing a cell transistor of a cell array region within a memory die region 11, and FIGS. 15 and 16 illustrate a method of manufacturing a core/peri transistor of a peripheral circuit region within a logic die region 21.

Referring to FIGS. 2 and 3, a first wafer 10 may include a plurality of memory die regions 11 spaced apart from each other in the first and second directions D1 and D2. Each of the memory die regions 11 may include a cell array region.

The first wafer 10 may include a first substrate structure. The first substrate structure may be a silicon-on-insulator (SOI) substrate. Accordingly, the first substrate structure may include a first bulk substrate 1100, a buried oxide layer 1110 and a second bulk substrate 1120′ sequentially stacked in the third direction D3. Each of the first and second bulk substrates 1100 and 1120′ may include a semiconductor material, e.g., single crystal silicon, single crystal germanium, single crystal silicon-germanium, etc.

In an example embodiment, the first wafer 10 may be a (100) wafer. That is, a direction connecting a geometric center of the first wafer 10 and a notch (or a flat) of the first wafer 10 may be the <100> direction. The <100> direction may include directions that are crystallographically equivalent to the direction. Among the horizontal directions substantially parallel to the upper surface of the first wafer 10, the direction connecting the geometric center and the notch (or the flat) may be defined as a second <100> direction (e.g., [010] direction), a direction substantially perpendicular to the second <100> direction may be defined as a first <100> direction (e.g., direction), and the first and second <100> directions may be substantially parallel to the first and second directions D1 and D2, respectively. In this case, in a coordinate system describing the crystallographic orientation of the first wafer 10, x, y and z directions may be substantially parallel to the first to third directions D1, D2 and D3, respectively.

In another example embodiment, the first wafer 10 may be a (320) wafer, a (310) wafer, (110) wafer, etc. In this case, the direction connecting the geometric center of the first wafer 10 and the notch (in the case of a (320) wafer, the <320> direction) may be substantially parallel to the second direction D2.

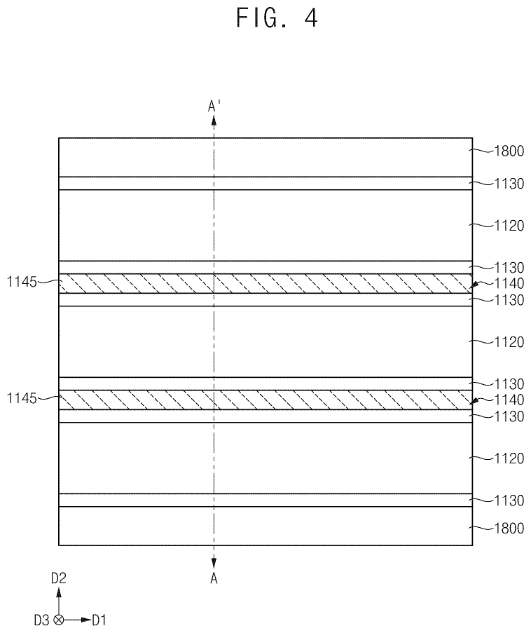

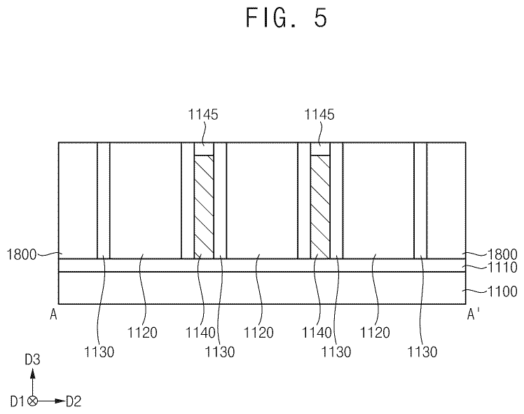

Referring to FIGS. 4 and 5, the second bulk substrate 1120′ of the first substrate structure may be patterned to form a preliminary first channel 1120.

In example embodiments, the preliminary first channel 1120 may extend in the first direction D1, and a plurality of preliminary first channels 1120 may be spaced apart from each other in the second direction D2. A first opening exposing an upper surface of the buried oxide layer 1110 may be formed between the preliminary first channels 1120 adjacent to each other in the second direction D2.

A first gate insulation layer may be formed on the preliminary first channel 1120 and the buried oxide layer 1110, and a portion of the first gate insulation layer on an upper surface of the buried oxide layer 1110 and an upper surface of the preliminary first channel 1120 may be removed by an anisotropic etching process to form a first gate insulation pattern 1120 at a sidewall of the first opening.

In example embodiments, the first gate insulation pattern 1130 may extend in the first direction D1 along a sidewall in the second direction D2 of the preliminary first channel 1120.

A first gate electrode layer may be formed on the preliminary first channel 1120, the first gate insulation pattern 1130 and the buried oxide layer 1110, and the first gate electrode layer may be planarized until the upper surface of the preliminary first channel 1120 and an upper surface of the first gate insulation pattern 1130 are exposed to form a first gate electrode 1140. The planarization process may include, for example, a chemical mechanical polishing (CMP) process and/or an etch back process.

In example embodiments, the first gate electrode 1140 may extend in the first direction D1, and a plurality of first gate electrodes 1140 may be spaced apart from each other in the second direction D2.

An upper portion of the first gate electrode 1140 may be removed by, for example, an etch back process, a first gate mask layer may be formed on the preliminary first channel 1120, the first gate insulation pattern 1130 and the first gate electrode 1140 to a sufficient height, and the first gate mask layer may be planarized until the upper surfaces of the preliminary first channel 1120 and the first gate insulation pattern 1130 are exposed to form a first gate mask 1145. The planarization process may include, for example, a chemical mechanical polishing (CMP) process and/or an etch back process.

In example embodiments, the first gate mask 1145 may extend in the first direction D1, and a plurality of first gate masks 1145 may be spaced apart from each other in the second direction D2.

The preliminary first channel 1120, the first gate insulation pattern 1130, the first gate electrode 1140 and the first gate mask 1145 formed outside a certain region may be removed to form a second opening exposing the upper surface of the buried oxide layer 1110, and a first insulating interlayer 1800 may be formed within the second opening.

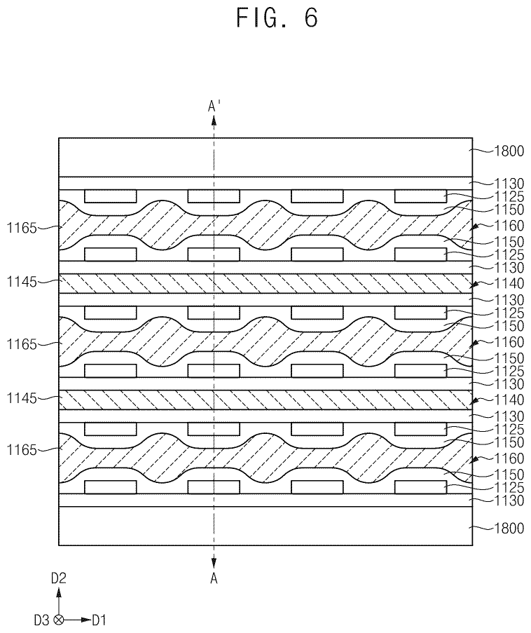

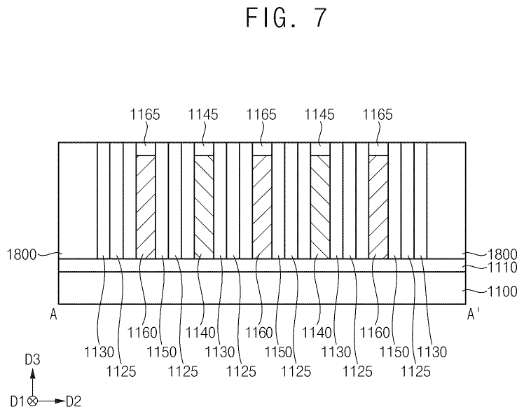

Referring to FIGS. 6 and 7, the preliminary first channel 1120 may be patterned to from a first channel 1125.

In an example embodiment, when the first wafer 10 is a (100) wafer, the first and second <100> directions may be substantially parallel to the first and second directions D1 and D2, respectively, so that {100} crystal plane of the second bulk substrate 1120′ may be substantially perpendicular to the first and second directions D1 and D2. Accordingly, {100} crystal plane of the first channel 1125 may be substantially parallel to the first interface of the first channel 1125 and the second gate insulation pattern 1150 in the first direction D1 and the second interface of the first channel 1125 and the second gate insulation pattern 1150 in the second direction D2.

In other embodiments, when the first wafer 10 is a (320) wafer, {320} crystal plane may be substantially parallel to the first and second interfaces of the first channel 1125 and the second gate insulation pattern 1150. When the first wafer 10 is a (310) wafer, {310} crystal plane may be substantially parallel to the first and second interfaces of the first channel 1125 and the second gate insulation pattern 1150. When the first wafer 10 is a (110) wafer, {110} crystal plane may be substantially parallel to the first and second interfaces of the first channel 1125 and the second gate insulation pattern 1150.

In example embodiments, a plurality of first channels 1125 may be spaced apart from each other along the first direction D1 at a sidewall in the second direction D2 of each of the first gate insulation patterns 1130 extending in the first direction D1. A third opening may be formed between the first gate insulation patterns 1130 adjacent to each other in the second direction D2 to expose the upper surface of the buried oxide layer 1110.

A second gate insulation layer may be formed on the first channel 1125, the first gate insulation pattern 1130 and the buried oxide layer 1110, and a portion of the second gate insulation layer on the upper surface of the buried oxide layer 1110, an upper surface of the first channel 1125, the upper surface of the first gate insulation pattern 1130 and an upper surface of the first gate mask 1145 may be removed by an anisotropic etching process to form a second gate insulation pattern 1150 at a sidewall of the third opening.

In example embodiments, the second gate insulation pattern 1150 may be extend in the first direction D1 along a sidewall in the second direction D2 of the first gate insulation pattern 1130 and a sidewall in the first and second directions D1 and D2 of the first channel 1125.

A second gate electrode layer may be formed on the buried oxide layer 1110, the first channel 1125, the first and second gate insulation patterns 1130 and 1150, the first gate mask 1145 and the first insulating interlayer 1800, the second gate electrode layer may be planarized until the upper surface of the first channel 1125, the upper surface of the first gate insulation pattern 1130, an upper surface of the second gate insulation pattern 1150, the upper surface of the first gate mask 1145 and an upper surface of the first insulating interlayer 1800 are exposed to form a second gate electrode 1160. The planarization process may include, for example, a chemical mechanical polishing (CMP) process and/or an etch back process.

In example embodiments, the second gate electrode 1160 may extend in the first direction D1, and a plurality of second gate electrodes 1160 may be spaced apart from each other in the second direction D2. In example embodiments, the second gate electrode 1160 may include an extension portion extending in the first direction D1 and protrusion portions protruding in the second direction D2 from each of opposite sidewalls in the second direction D2.

An upper portion of the second gate electrode 1160 may be removed by, for example, an etch back process, a second gate mask layer may be formed on the first channel 1125, the first and second gate insulation patterns 1130 and 1150, the first gate mask 1145 and the first insulating interlayer 1800 to a sufficient height, and the second gate mask layer may be planarized until the upper surfaces of the first channel 1125, the first and second gate insulation patterns 1130 and 1150, the first gate mask 1145 and the first insulating interlayer 1180 are exposed to form a second gate mask 1165. The planarization process may include, for example, a chemical mechanical polishing (CMP) process and/or an etch back process.

In example embodiments, the second gate mask 1165 may extend in the first direction D1, and a plurality of second gate masks 1165 may be spaced apart from each other in the second direction D2.

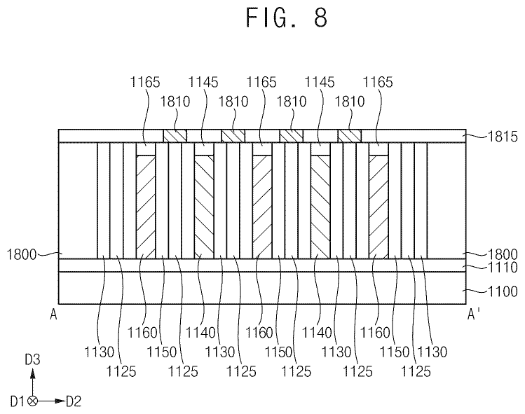

Referring to FIG. 8, a first semiconductor layer may be formed on the first channel 1125, the first and second gate insulation patterns 1130 and 1150, the first and second gate masks 1145 and 1165 and first insulating interlayer 1800, and the first semiconductor layer may be patterned to form a first semiconductor pattern 1810.

In example embodiments, a plurality of first semiconductor patterns 1810 may be spaced apart from each other in the first and second directions D1 and D2 to contact the upper surfaces of the first channels 1125, respectively. The first semiconductor pattern 1810 may include silicon doped with impurities and may serve as a source of the cell transistor.

A second insulating interlayer 1815 may be formed on the first channel 1125, the first and second gate insulation patterns 1130 and 1150, the first and second gate masks 1145 and 1165 and the first insulating interlayer 1800 to cover a sidewall of the first semiconductor pattern 1810.

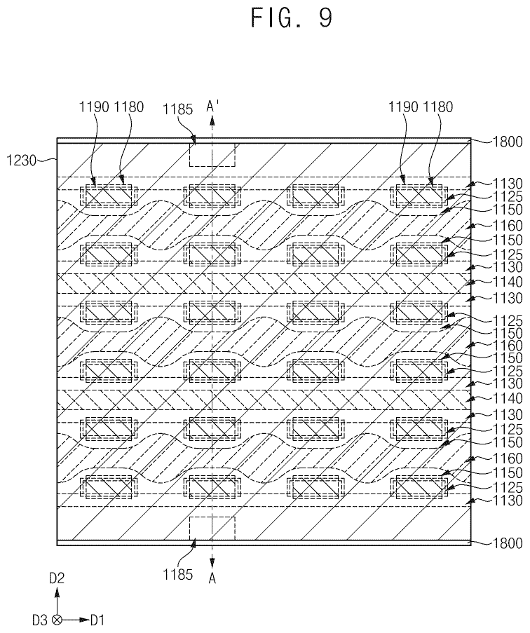

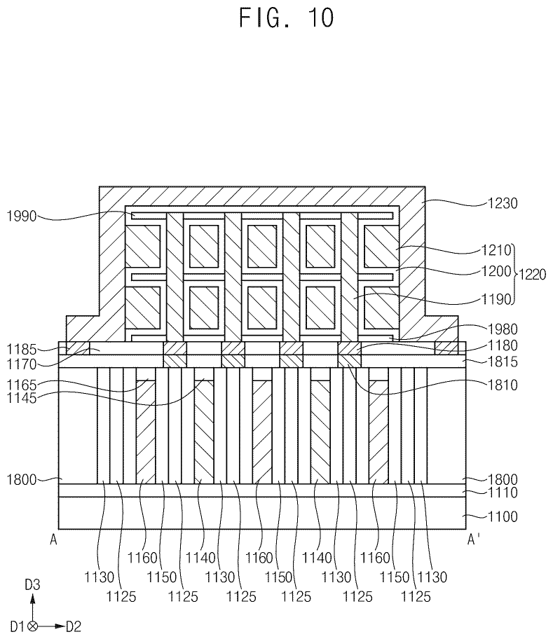

Referring to FIGS. 9 and 10, a third insulating interlayer 1170 may be formed on the first semiconductor pattern 1810 and the second insulating interlayer 1815, and first and second pads 1180 and 1185 extending through the third insulating interlayer 1170 may be formed.

In example embodiments, a plurality of first pads 1180 may be spaced apart from each other in the first and second directions D1 and D2 to contact upper surfaces of the first semiconductor patterns 1810, respectively. The second pad 1185 may be formed to extend through a portion of the third insulating interlayer 1170 on the first insulating interlayer 1800.

A first capacitor 1220 and a first plate electrode 1230 may be formed on the third insulating interlayer 1170 and the first and second pads 1180 and 1185. The first capacitor 1220 and the first plate electrode 1230 may be formed by following processes.

A first etch stop layer 1980 may be formed on the third insulating interlayer 1170 and the first and second pads 1180 and 1185, and a mold layer and a support layer 1990 may be alternately and repeatedly stacked on the first etch stop layer 1980. The first etch stop layer 1980 may include an insulating nitride, e.g., silicon boronitride, the mold layer may include an oxide, e.g., silicon oxide, and the support layer 1990 may include an insulating nitride, e.g., silicon nitride.

A fourth opening may be formed through the support layer 1990, the mold layer and the first etch stop layer 1980 to expose an upper surface of the first pad 1180, a first capacitor electrode layer may be formed on the upper surface of the first pad 1180 exposed by the fourth opening, a sidewall of the fourth opening and an upper surface of an uppermost support layer 1990, and the first capacitor electrode layer may be planarized until an upper surface of the uppermost support layer 1990 is exposed to form a first capacitor electrode 1190 within the fourth opening.

The planarization process may include, e.g., a chemical mechanical polishing (CMP) process and/or an etch back process.

The support layer 1990 and the mold layer may be partially removed to form a fifth opening exposing the upper surface of the first etch stop layer 1980, and the mold layer may be removed through the fifth opening.

In example embodiments, the mold layer may be removed by a wet etching process, and accordingly, a sixth opening may be formed to expose a sidewall of the first capacitor electrode 1190 and the upper surface of the first etch stop layer 1980. The support layers 1990 may remain on the sidewall of each of the first capacitor electrodes 1190, and accordingly, surface of each of the support layers 1990 may be exposed by the sixth opening.

A first dielectric layer 1200 may be formed on the sidewall of each of the first capacitor electrodes 1190, the upper surface of the first etch stop layer 1980 and the surface of each of the support layers 1990 exposed by the sixth opening, and a second capacitor electrode layer may be formed on the first dielectric layer 1200 to fill a remaining portion of the sixth opening. The first dielectric layer 1200 and the second capacitor electrode layer may also be stacked on an upper surface of the first capacitor electrode 1190 and the upper surface of the uppermost support layer 1990.

A wet etching process may be performed on the second capacitor electrode layer to form a second capacitor electrode 1210 within the sixth opening. The first capacitor electrode 1190, the first dielectric layer 1200 and the second capacitor electrode 1210 may collectively form the first capacitor 1220.

The first plate electrode 1230 may be formed on an upper surface and a sidewall of the first capacitor 1220, an upper surface of the third insulating interlayer 1170 and an upper surface of the second pad 1185. The first plate electrode 1230 may contact the upper surface of the second pad 1185.

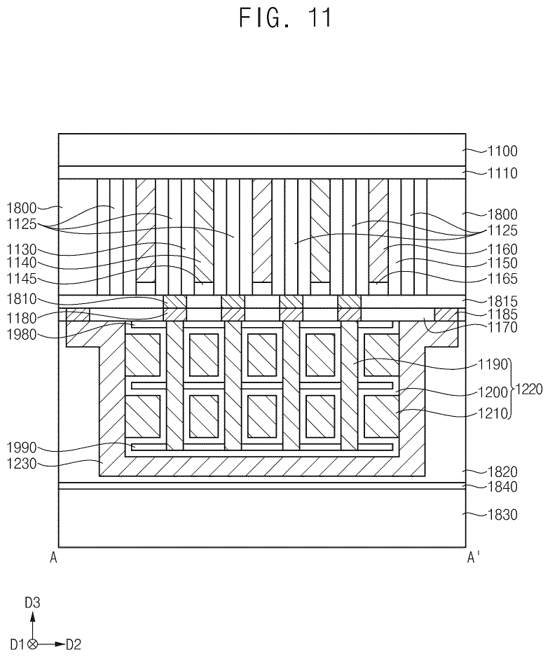

Referring to FIG. 11, a fourth insulating interlayer 1820 may be formed on the first plate electrode 1230 and the third insulating interlayer 1170, and a second substrate 1830 may be bonded to an upper surface of the fourth insulating interlayer 1820 by using a first bonding layer 1840.

The second substrate 1830 may include a semiconductor material, e.g., silicon, or an insulating material, e.g., glass, and the first bonding layer 1840 may include, e.g., silicon carbonitride, silicon oxide, etc.

A structure including the first substrate structure and the second substrate 1830 may be turned over, and hereinafter, the following description may be based on a state in which top and bottom of the structure is inverted.

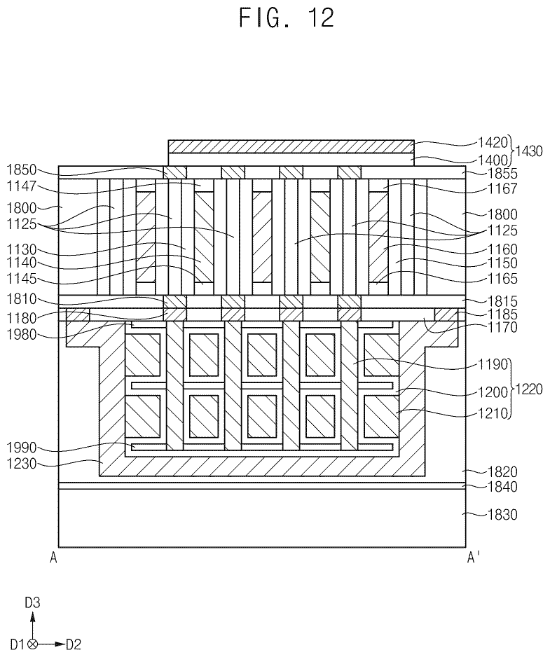

Referring to FIG. 12, the first bulk substrate 1100 and the buried oxide layer 1110 of the first substrate structure may be removed by, for example, a grinding process, thereby exposing upper surfaces of the first channel 1125, the first and second gate insulation patterns 1130 and 1150, the first and second gate electrodes 1140 and 1160 and the first insulating interlayer 1800.

Upper portions of the first and second gate electrodes 1140 and 1160 may be removed by, e.g., an etch back process; a third gate mask layer may be formed on the first channel 1125, the first and second gate insulation patterns 1130 and 1150, the first and second gate electrodes 1140 and 1160 and the first insulating interlayer 1800 to sufficient height. The third gate mask may be planarized until the upper surfaces of the first channel 1125, the first and second gate insulation patterns 1130 and 1150 and the first insulating interlayer 1800 are exposed. Accordingly, third and fourth gate masks 1147 and 1167 may be formed on the first and second gate electrodes 1140 and 1160, respectively. The planarization process may include, e.g., a chemical mechanical polishing (CMP) process and/or an etch back process.

In example embodiments, the third gate mask 1147 may extend in the first direction D1, and a plurality of third gate masks 1147 may be spaced apart from each other in the second direction D2. In example embodiments, the fourth gate mask 1167 may extend in the first direction D1, and a plurality of fourth gate masks 1167 may be spaced apart from each other in the second direction D2.

The first gate mask 1145, the first gate electrode 1140, the third gate mask 1147 and the first gate insulation pattern 1130 may collectively form a first gate structure. The second gate mask 1165, the second gate electrode 1160, the fourth gate mask 1167 and the second gate insulation pattern 1150 may collectively form a second gate structure. The first and second gate structures may be formed alternately and repetitively along the second direction D2.

A second semiconductor layer may be formed on the first channel 1125, the first and second gate insulation patterns 1130 and 1150, the third and fourth gate masks 1147 and 1167 and first insulating interlayer 1800, and the second semiconductor layer may be patterned to form a second semiconductor pattern 1850. In example embodiments, a plurality of second semiconductor patterns 1850 may be spaced apart from each other along the first and second directions D1 and D2 to contact upper surfaces of the first channels 1125, respectively. The second semiconductor pattern 1850 may include, for example, silicon doped with impurities.

A fifth insulating interlayer 1855 may be formed on the first channel 1125, the first and second gate insulation patterns 1130 and 1150, the third and fourth gate masks 1147 and 1167 and the first insulating interlayer 1800 to cover a sidewall of the second semiconductor pattern 1850.

A first bit line structure 1430 may be formed on the second semiconductor pattern 1850 and the fifth insulating interlayer 1855. In example embodiments, the first bit line structure 1430 may extend in the second direction D2, and a plurality of first bit line structures 1430 may be spaced apart from each other in the first direction D1. Each of the first bit line structures 1430 may contact upper surfaces of the second semiconductor patterns 1850 arranged in the second direction D2.

In an example embodiment, each of the first bit line structures 1430 may include first and second conductive patterns 1400 and 1420 stacked in the third direction D3. The third conductive pattern 1400 may include, for example, polysilicon doped with impurities, and the second conductive pattern 1420 may include, for example, a metal.

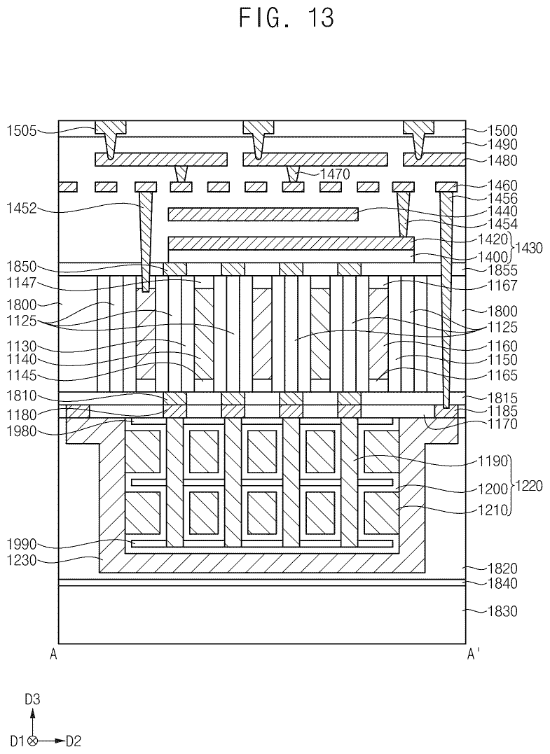

Referring to FIG. 13, first to third wirings 1440, 1460 and 1480, first to third contact plugs 1452, 1454 and 1456 and a first via 1470 may be formed on the first bit line structure 1430, and a sixth insulating interlayer 1490 may be formed on the second semiconductor pattern 1850 and the fifth insulating interlayer 1855 to cover the first to third wirings 1440, 1460 and 1480, the first to third contact plugs 1452, 1454 and 1456 and the first via 1470.

A second bonding layer 1500 may be formed on the sixth insulating interlayer 1490, and a first bonding structure 1505 may be formed to extend through the second bonding layer 1500 and an upper portion of the sixth insulating interlayer 1490.

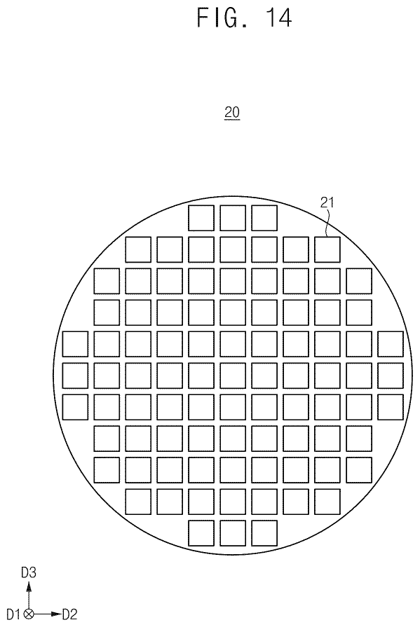

Referring to FIGS. 14 and 15, the second wafer 20 may include a plurality of logic die regions 21 spaced apart from each other in the first and second directions D1 and D2. Each of the logic die regions 21 may include a peripheral circuit region.

The second wafer 20 may include a semiconductor material, e.g., single crystal silicon, single crystal germanium, single crystal silicon-germanium, etc.

In an example embodiment, when the second wafer 20 includes single crystal silicon-germanium, the second wafer 20 may be a (110) wafer. That is, a direction connecting a geometric center of the second wafer 20 and a notch (or a flat) of the second wafer 20 may be the <110> direction. The <110> direction may include directions that are

crystallographically equivalent to the direction. Among the horizontal directions substantially parallel to the upper surface of the second wafer 20, the direction connecting the geometric center and the notch (or the flat) may be defined as a second <110> direction (e.g.,—[110] direction), a direction substantially perpendicular to the second <110> direction may be defined as a first <110> direction (e.g., direction), and the first and second <110> directions may be substantially parallel to the first and second directions D1 and D2, respectively. In this case, in a coordinate system describing the crystallographic orientation of the second wafer 20, an x direction may be substantially parallel to a direction forming 45 degrees with the first direction D1 and 135 degrees with the second direction D2, a y direction may be substantially parallel with a direction forming 45 degrees with each of the first and second directions D1 and D2, and a z direction may be substantially parallel to the third direction D3.

In another example embodiment, the second wafer 20 may be a (320) wafer, a (310) wafer, (100) wafer, etc. In this case, the direction connecting the geometric center of the second wafer 20 and the notch of the second wafer 20 (in the case of a (320) wafer, the <320> direction) may be substantially parallel a direction of the current (that is, the second direction D2) flowing in the second channel.

The third substrate 1510 may be a portion of the second wafer 20.

Hereinafter, a method of manufacturing a core/peri transistor of the peripheral circuit region within the logic die region 21 is illustrated.

A first isolation pattern 1540 may be formed at an upper portion of the third substrate 1510.

A third gate structure 1630 may be formed on the third substrate 1510 and a first impurity region 1640 may be formed at an upper portion of the third substrate 1510 adjacent to the third gate structure 1630. Accordingly, the core/peri transistor including the third gate structure 1630 and the first impurity region 1640 may be formed.

A seventh insulating interlayer 1650 may be formed on the third substrate 1510 to cover the core/peri transistor, and a fourth contact plug 1660 may be formed through the seventh insulating interlayer 1650 to contact an upper surface of the first impurity region 1640.

Fourth to sixth wirings 1670, 1690 and 1710, a fifth contact plug 1680 and a second via 1700 may be formed on the seventh insulating interlayer 1650, and an eighth insulating interlayer 1720 may be formed to cover the fourth to sixth wirings 1670, 1690 and 1710, the fifth contact plug 1680 and the second via 1700.

A third bonding layer 1730 may be formed on the eighth insulating interlayer 1720, and a second bonding structure 1735 may be formed to extend through the third bonding layer 1730 and an upper portion of the eighth insulating interlayer 1720. The second bonding structure 1735 may be formed at a position corresponding to the first bonding structure 1505.

Referring to FIG. 1 again, after turning over the second substrate 1830, the second bonding layer 1500 may be brought into contact with the third bonding layer 1730, thereby bonding the second substrate 1830 to the third substrate 1510. The first bonding structure 1505 may contact the second bonding structure 1735. Accordingly, manufacturing of the first semiconductor device may be completed.

As described above, the memory die region 11 in which the cell transistors are formed and the logic die region 21 in which the core/peri transistors are formed may be formed on separate wafers. In the case of the first wafer 10 on which the cell transistor is formed, crystal orientation may be adjusted so that the first and second interfaces of the first channel 1125 may be substantially parallel to the {100} crystal plane of silicon to improve DIT. In the case of the second wafer on which the core/peri transistor is formed, crystal orientation may be adjusted so that the {110} crystal plane of silicon-germanium may be substantially perpendicular to the direction of the current flowing in the second channel to increase electron mobility. Wafer orientation may be adjusted based on the characteristics of each region of the first semiconductor device, and thus, electrical characteristics of the first semiconductor device may be improved.

FIG. 16 is a cross-sectional view illustrating a second semiconductor device according to example embodiments.

The second semiconductor device may be substantially the same as or similar to the first semiconductor device illustrated with reference to FIG. 1, except for the first bit line structure 1430, the second semiconductor pattern 1850, the first channel 1125 and the first semiconductor pattern 1810 being formed by an epitaxial growth process, the first bit line structure 1430 including only a single pattern, and further including a ninth insulating interlayer 1905 covering a sidewall of the first bit line structure 1430. Thus, repeated explanations are omitted herein.

Referring to FIG. 16, the first bit line structure 1430 may include, for example, single crystal silicon doped with impurities, and the ninth insulating interlayer 1905 may include an oxide, for example, silicon oxide or low dielectric materials.

In example embodiments, the first bit line structure 1430, the second semiconductor pattern 1850 and the first channel 1125 may each include a semiconductor material, e.g., single crystal silicon, single crystal germanium, single crystal silicon-germanium, etc. The first bit line structure 1430, the second semiconductor pattern 1850 and the first channel 1125 may all have a same crystal orientation.

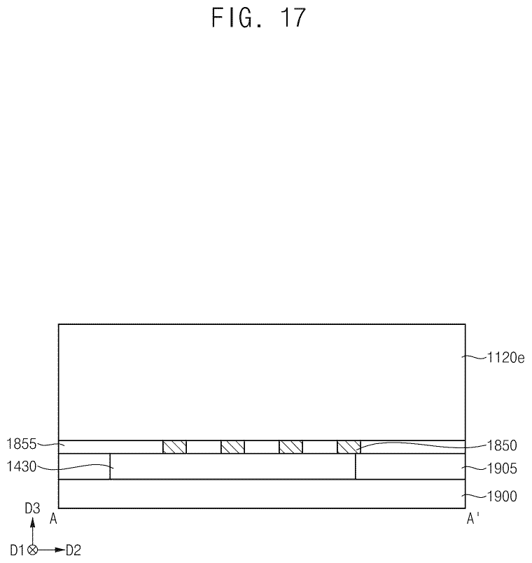

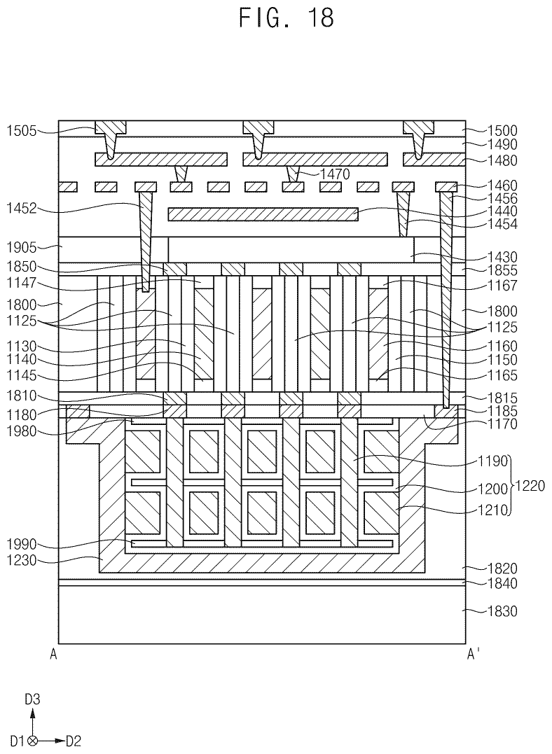

FIGS. 17 to 18 are cross-sectional views illustrating a method of forming a second semiconductor device in accordance with example embodiments.

This method may include processes substantially the same as or similar to those illustrated with reference to FIGS. 1 to 15, except for first forming the first bit line structure 1430 and then sequentially forming the second semiconductor pattern 1850, the first channel 1125 and the first semiconductor pattern 181. Thus, repeated explanations thereof are omitted herein.

Referring to FIG. 17, an epitaxial growth process using an upper surface of a fourth substrate 1900 as a seed may be performed to form a first bit line layer structure, and a first bit line structure 1430 may be formed by performing a patterning process on the first bit line layer structure.

The fourth substrate 1900 may be a portion of a third wafer. The third wafer may be a (100) wafer, a (320) wafer, a (310) wafer, a (110) wafer, etc. A direction connecting a geometric center of the third wafer and a notch (or a flat) of the third wafer (in the case of a (100) wafer, the <100> direction) may be substantially parallel to the second direction D2.

The first bit line structure 1430 may include, for example, a single crystal semiconductor material doped with impurities.

An epitaxial growth process using an upper surface of the first bit line structure 1430 as a seed may be performed to form a second semiconductor layer, and the second semiconductor layer may be patterned to form the second semiconductor pattern 1850.

An epitaxial growth process using an upper surface of the second semiconductor pattern 1850 as a seed may be performed to form a preliminary first channel layer 1120e. Thereafter, processes substantially the same as or similar to those illustrated with reference to FIGS. 4 to 10 may be performed.

Since the first bit line structure 1430, the second semiconductor pattern 1850 and the first channel 1125 may all be formed by performing an epitaxial growth process based on the fourth substrate 1900 containing single crystal silicon, they may all have a same crystal orientation as the fourth substrate 1900.

Referring to FIG. 18, a structure including the fourth substrate 1900 may be turned over by performing processes substantially the same or similar to those illustrated with reference to FIG. 11, and thus, top and bottom of the structure may be inverted.

Thereafter, processes substantially the same or similar to those illustrated with reference to FIG. 13 may be performed to form the first to third contact plugs 1452, 1454 and 1456, the first to third wirings 1440, 1460 and 1480, the first via 1470, the sixth insulating interlayer 1490, the second bonding layer 1500 and the first bonding structure 1505.

Referring again to FIG. 16, after turning over the fourth substrate 1900, the second bonding layer 1500 may be brought into contact with the third bonding layer 1730, thereby bonding the second substrate 1830 to the third substrate 1510. The first bonding structure 1505 may contact the second bonding structure 1735. Accordingly, manufacturing of the second semiconductor device may be completed.

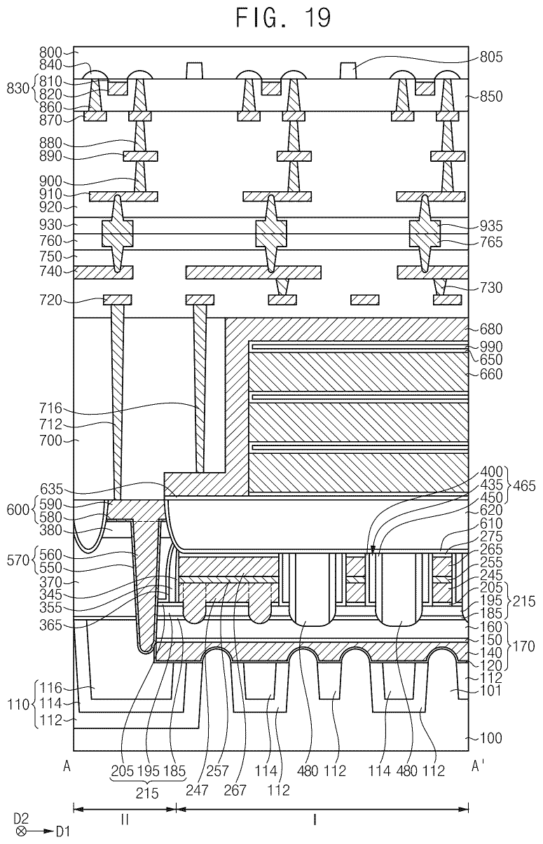

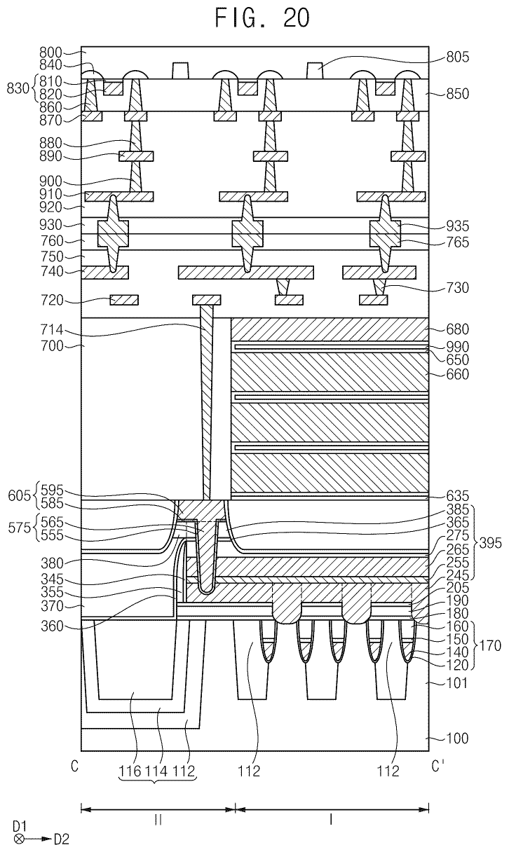

FIGS. 19 and 20 are cross-sectional views illustrating a third semiconductor device according to example embodiments.

Referring to FIGS. 19 and 20, in the third semiconductor device, a peripheral circuit region including a core/peri transistor may be formed on a cell array region including a cell transistor.

That is, the third semiconductor device may have a cell over periphery (COP) structure, where the cell array region is formed over the peripheral circuit region. However, the concept of the present invention is not limited thereto, and the third semiconductor device of FIG. 1 may have a periphery over cell (POC) structure, where the peripheral circuit region is formed over the cell array region.

Hereinafter, two directions among horizontal directions that are substantially parallel to an upper surface of each of fifth and sixth substrates 100 and 800 of the third semiconductor device, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of each of the fifth and sixth substrate 100 and 800 of the third semiconductor device may be referred to as a vertical direction.

The third semiconductor device may include an active pattern 101, a fourth gate structure 170, a second bit line structure 395, a dummy bit line structure 397, a sixth contact plug structure, seventh and eighth contact plugs 570 and 575, seventh and eighth wirings 600 and 605, a second capacitor 670, ninth to eleventh contact plugs 712, 714 and 716, a second wiring structure, a fifth gate structure 830 and second impurity region 840 on a fifth substrate 100.

The third semiconductor device may further include an isolation structure 110, an insulation pattern structure 215, a first spacer structure, fourth and fifth insulation patterns 410 and 420, a second spacer structure 465, a sixth spacer 490, a fence pattern 480, tenth, twelfth, thirteenth, fourteenth and fifteenth insulating interlayer 370, 700, 750, 850 and 920, an eleventh insulating interlayer and a fifth isolation pattern 805.

The fifth substrate 100 may include a semiconductor material, e.g., single crystal silicon, single crystal germanium, single crystal silicon-germanium, etc. The fifth substrate 100 may be a portion of a fourth wafer, and the fourth wafer may be a (100) wafer, a (320) wafer, a (310) wafer, a (110) wafer, etc. A direction connecting a geometric center of the fourth wafer and a notch (or a flat) of the fourth wafer (in the case of a (100) wafer, the <100> direction) may be substantially parallel to the second direction D2.

In an example embodiment, the fifth substrate 100 may include single crystal silicon, and have a crystal orientation where {100} crystal plane is substantially perpendicular to the second direction D2. Accordingly, DIT of the fourth gate structure 170 and the active pattern 101 may be improved.

The fifth substrate 100 may include first and second regions I and II. The first region I of the fifth substrate 100 may be a cell array region on which memory cells are formed, and the second region II of the fifth substrate 100 may be an extension region on which contact plugs that transmit electrical signals to the memory cells are formed. The first and second regions I and II of the fifth substrate 100 may collectively form a cell region. Only a portion of the first region I and a portion of the second region II adjacent thereto in the first and second directions D1 and D2 are illustrated in the drawings.

The active pattern 101 may be formed by removing an upper portion of the fifth substrate 100 to form a recess structure. The active pattern 101 may extend in the third direction D3 on the first region I of the fifth substrate 100 and the second region II of the fifth substrate 100 adjacent thereto, and a plurality of active patterns 101 may be spaced apart from each other in each of the first and second directions D1 and D2. A sidewall of the active pattern 101 may be covered by the isolation structure 110. The active pattern 101 may include a substantially same material as the fifth substrate 100.

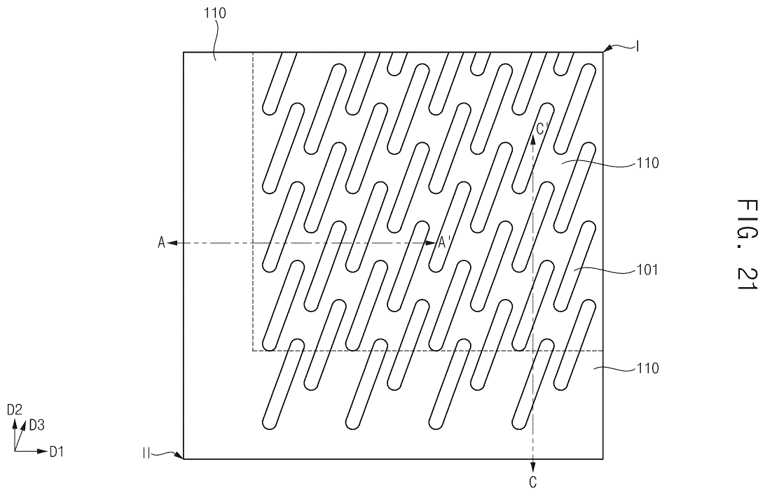

Referring to FIGS. 19 and 20 together with FIGS. 21 to 23, the isolation structure 110 may include second, third and fourth isolation patterns 112, 114 and 116 sequentially stacked on an inner wall of the third recess 106. However, the second and third isolation patterns 112 and 114 may be formed in the second recess 104 having a width smaller than that of the third recess 106, and the second isolation pattern 112 may be formed in the first recess 102 having a width smaller than that of the second recess 104.

Each of the second and fourth isolation patterns 112 and 116 may include an oxide, e.g., silicon oxide, and the third isolation pattern 114 may include an insulating nitride, e.g., silicon nitride.

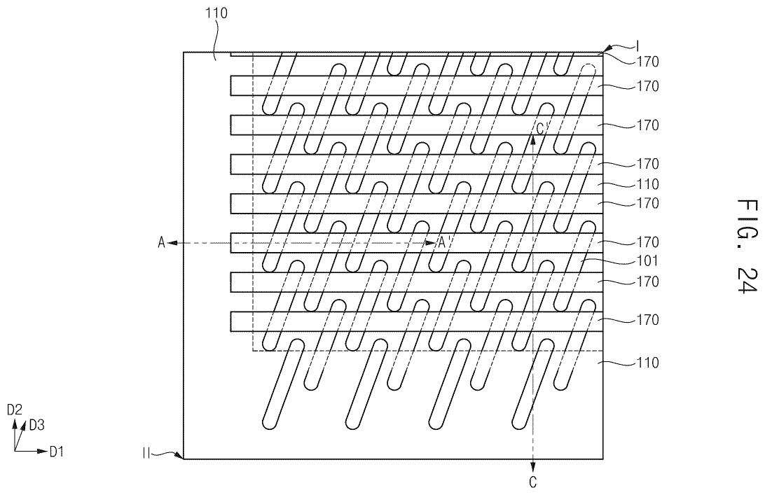

Referring to FIGS. 19 and 20 together with FIGS. 24, the fourth gate structure 170 may be formed within a fourth recess extending through upper portions of the active pattern 101 and the isolation structure 110 on the first region I of the fifth substrate 100 and the second region II of the fifth substrate 100 adjacent to the first region I of the fifth substrate 100 in the first direction D1.

The fourth gate structure 170 may include a fourth gate insulation pattern 120 formed on a bottom and a sidewall of the fourth recess, a fourth gate electrode formed on a portion of the fourth gate insulation pattern 120 on the bottom and a lower sidewall of the fourth recess, and a fourth gate mask 160 formed on the fourth gate electrode and filling an upper portion of the fourth recess. The fourth gate electrode may include third and fourth conductive patterns 140 and 150 sequentially stacked in the third direction D3, and the fourth gate structure 170 may further include a first barrier pattern disposed between the fourth gate insulation pattern 120 and the third conductive pattern 140.

The fourth gate insulation pattern 120 may include an oxide, e.g., silicon oxide, the first barrier pattern may include a metal nitride, e.g., titanium nitride, tantalum nitride, etc., the third conductive pattern 140 may include a metal, a metal nitride, a metal silicide, doped polysilicon, etc., the fourth conductive pattern 150 may include doped polysilicon, and the fifth gate mask 160 may include a nitride, e.g., silicon nitride.

In example embodiments, the fourth gate structure 170 may extend in the first direction D1 on the first region I of the fifth substrate 100 and the second region II of the fifth substrate 100 adjacent to the first region I of the fifth substrate 100 in the first direction D1, and a plurality of fourth gate structures 170 may be spaced apart from each other in the second direction D2. End portions in the first direction D1 of the fourth gate structures 170 may be aligned with each other in the second direction D2 on the second region II of the fifth substrate 100.

The fourth gate structure 170 and a third channel, which is a portion of the fifth substrate 100 below the fourth gate structure 1630, may collectively form a cell transistor.

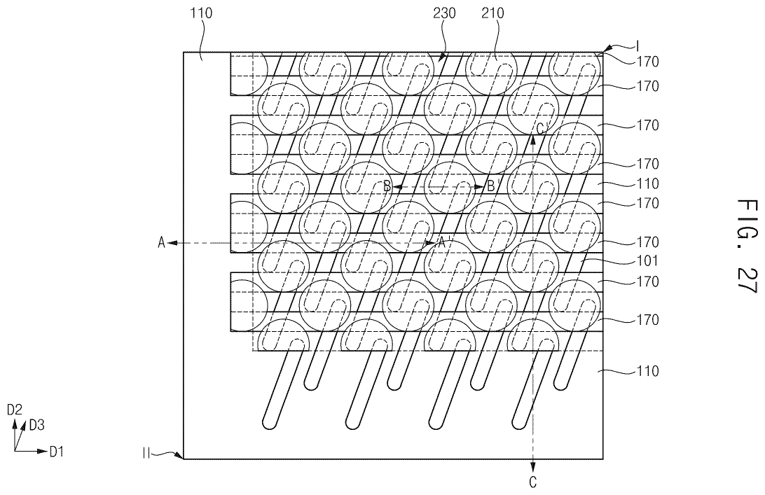

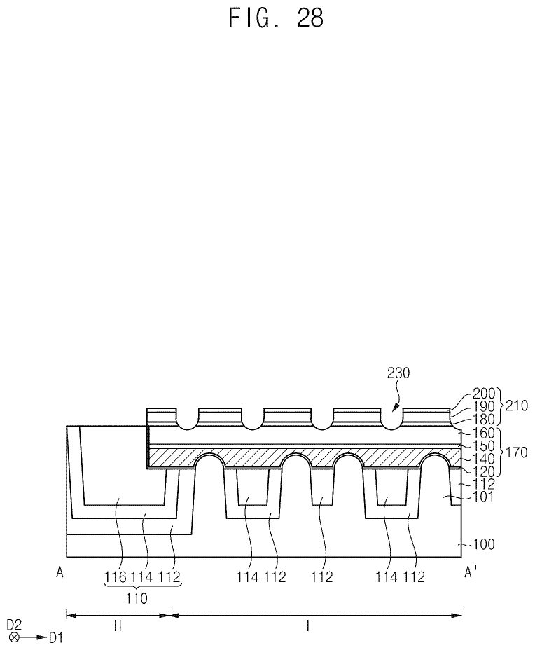

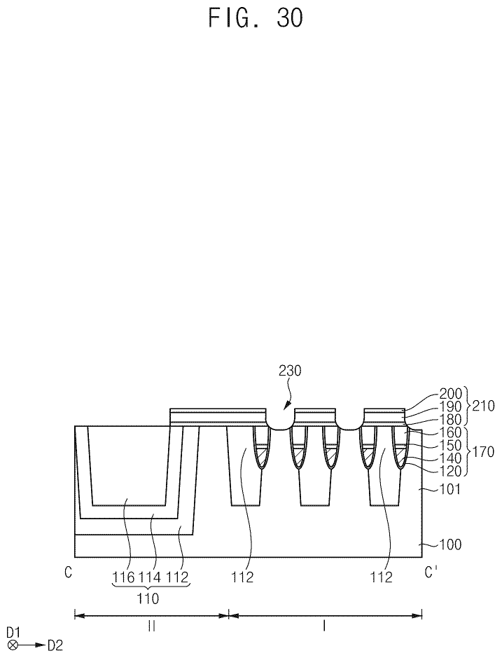

Referring to FIGS. 19 and 20 together with FIGS. 27 to 30, a seventh opening 230 extending through an insulation layer structure 210 and exposing upper surfaces of the active pattern 101, the isolation structure 110 and the fifth gate mask 160 of the fourth gate structure 170 may be formed, and an upper surface of a central portion in the third direction D3 of the active pattern 101 may be exposed by the seventh opening 230.

In example embodiments, an area of a bottom of the seventh opening 230 may be greater than an area of the upper surface of the active pattern 101 exposed by the seventh opening 230. Thus, the seventh opening 230 may also expose an upper surface of a portion of the isolation structure 110 adjacent to the active pattern 101. Additionally, the seventh opening 230 may extend through upper portions of the active pattern 101 and the portion of the isolation structure 110 adjacent thereto, and thus the bottom of the seventh opening 230 may be lower than an upper surface of each of opposite edge portions in the third direction D3 of the active pattern 101.

The second bit line structure 395 may include a fifth conductive pattern 245, a second barrier pattern 255, a sixth conductive pattern 265, a second mask 275, a second etch stop pattern 365 and a first capping pattern 385 sequentially stacked in the vertical direction on the seventh opening 230 or the insulation pattern structure 235 on the first region I of the fifth substrate 100 and the second region II of the fifth substrate 100 adjacent thereto in the second direction D2. The fifth conductive pattern 245, the second barrier pattern 255 and the sixth conductive pattern 265 may collectively form a conductive structure, and the second mask 275, the second etch stop pattern 365 and the first capping pattern 385 may collectively form an insulation structure.

The fifth conductive pattern 245 may include, e.g., doped polysilicon, the second barrier pattern 265 may include a metal nitride, e.g., titanium nitride, or a metal silicon nitride, e.g., titanium silicon nitride, the sixth conductive pattern 265 may include a metal, e.g., tungsten, and each of the second mask 275, the second etch stop pattern 365 and the first capping pattern 385 may include an insulating nitride, e.g., silicon nitride.

In example embodiments, the second bit line structure 395 may extend in the second direction D2 on the first region I of the fifth substrate 100 and the second region II of the fifth substrate 100 adjacent thereto in second direction D2, and a plurality of second bit line structures 395 may be spaced apart from each other in the first direction D1.

The dummy bit line structure 397 may include a seventh conductive pattern 247, a third barrier pattern 257, an eighth conductive pattern 267, a third mask 277, a third etch stop pattern 367 and a second capping pattern 387 sequentially stacked in the vertical direction on the first region I of the fifth substrate 100 and of the second region II of the fifth substrate 100 adjacent thereto in the second direction D2. In example embodiments, the dummy bit line structure 397 may extend in the second direction D2 on the first region I of the fifth substrate 100 and the second region II of the fifth substrate 100 adjacent thereto in second direction D2.

The first spacer structure may be formed at a sidewall in the second direction D2 of the second bit line structure 395 on the second region II of the fifth substrate 100, and a sidewall in the first and second direction D1 and D2 of the dummy bit line structure 395 on the second region II of the fifth substrate 100 and the first region I of the fifth substrate 100 adjacent thereto in the first direction D1. The first spacer structure may include first and second spacers 345 and 355 sequentially stacked in the horizontal direction at the sidewalls of the second bit line structure 395 and the dummy bit line structure 397.

The first spacer 345 may include a nitride, e.g., silicon nitride, and the second spacer 355 may include an oxide, e.g., silicon oxide.

However, the structure of the first spacer structure may not be limited thereto, and the first spacer structure may include a single spacer or more than two spacers sequentially stacked.

The fourth and fifth insulation patterns 410 and 420 may be formed in the seventh opening 230, and may contact a lower sidewall of the second bit line structure 395. The fourth insulation pattern 410 may include an oxide, e.g., silicon oxide, and the fifth insulation pattern 420 may include an insulating nitride, e.g., silicon nitride.

The insulation pattern structure 215 may be formed on the active pattern 101 and the isolation structure 110 under the second bit line structure 395 on the first region I of the fifth substrate 100, and may include first, second and third insulation patterns 185, 195 and 205 sequentially stacked in the vertical direction. The first and third insulation patterns 185 and 205 may include an oxide, e.g., silicon oxide, and the second insulation pattern 195 may include an insulating nitride, e.g., silicon nitride.

The sixth contact plug structure may include a lower contact plug 475, an ohmic contact pattern 500 and an upper contact plug 549 sequentially stacked in the vertical direction on the active pattern 101 and the isolation structure 110.

The lower contact plug 475 may contact the upper surface of each of opposite edge portions in the third direction D3 of the active pattern 101. In example embodiments, a plurality of lower contact plugs 475 may be spaced apart from each other in the second direction D2 between the second bit line structures 395 and between the second bit line structure 395 and the dummy bit line structure 397. The fence pattern 480 may be formed between neighboring ones of the lower contact plugs 475 in the second direction D2. The fence pattern 480 may include an insulating nitride, e.g., silicon nitride.

The lower contact plug 475 may include, e.g., doped polysilicon, the ohmic contact pattern 500 may include, e.g., titanium silicide, cobalt silicide, nickel silicide, etc.

The upper contact plug 549 may include a first metal pattern 545 and a fourth barrier pattern 535 covering a lower surface of the first metal pattern 545. The first metal pattern 545 may include a metal, e.g., tungsten, and the fourth barrier pattern 535 may include a metal nitride, e.g., titanium nitride.

In example embodiments, a plurality of upper contact plugs 549 may be spaced apart from each other in the first and second directions D1 and D2, and may be arranged in a honeycomb pattern or a lattice pattern on the first region I of the fifth substrate 100 in a plan view. Each of the upper contact plugs 549 may have a shape of, e.g., a circle, an ellipse, or a polygon in a plan view.

The second spacer structure 465 may include a third spacer 400 covering sidewalls of the second bit line structure 395, the third insulation pattern 205 and the dummy bit line structure 397, an air spacer 435 on a lower outer sidewall of the third spacer 400, and a fifth spacer 450 on an outer sidewall of the air spacer 435, a sidewall of the insulation pattern structure 215, and upper surfaces of the fourth and fifth insulation patterns 410 and 420.

Each of the third and fifth spacers 400 and 450 may include an insulating nitride, e.g., silicon nitride, and the air spacer 435 may include air.

The sixth spacer 490 may be formed on an outer sidewall of a portion of the third spacer 400 on upper sidewalls of the second bit line structure 395 and the dummy bit line structure 397, and may cover an upper end of the air spacer 435 and an upper surface of the fifth spacer 450. The sixth spacer 490 may include an insulating nitride, e.g., silicon nitride.

The seventh contact plug 570 may include a second metal pattern 560 and a fifth barrier pattern 550 covering a lower surface of the second metal pattern 560. The seventh contact plug 570 may extend through the capping layer 380 and the tenth insulating interlayer 370 to contact the third conductive pattern 140 of the fourth gate structure 170. In example embodiments, a plurality of seventh contact plugs may be spaced apart from each other in the second direction D2 on the second region II of the fifth substrate 100 adjacent to the first region I of the fifth substrate 100 in the first direction D1.

The seventh wiring 600 may include a third metal pattern 590 and a sixth barrier pattern 580 covering a lower surface of the third metal pattern 590. In example embodiments, the seventh wiring 600 may be electrically connected to the third conductive pattern 140 through the seventh contact plug 570. Accordingly, the seventh wiring 600 may apply an electrical signal to the fourth gate structure 170.

The eighth contact plug 575 may include a fourth metal pattern 565 and a seventh barrier pattern 555 covering a lower surface of the fourth metal pattern 565. The eighth contact plug 575 may extend through the capping layer 380 and the tenth insulating interlayer 370 to contact the fifth conductive pattern 245 of the second bit line structure 395. In example embodiments, a plurality of eighth contact plugs 575 may be spaced apart from each other in the first direction D1 on the second region II of the fifth substrate 100 adjacent to the first region I of the fifth substrate 100 in the second direction D2.

The eighth wiring 605 may include a fifth metal pattern 595 and an eighth barrier pattern 585 covering a lower surface of the fifth metal pattern 595. In example embodiments, the eighth wiring 605 may be electrically connected to the fifth conductive pattern 245 through the eighth contact plug 575. Accordingly, the eighth wiring may apply an electrical signal to the second bit line structure 395.

Each of the second to fifth metal patterns 560, 590, 565 and 595 may include a metal, e.g., tungsten, and each of the fifth to eighth barrier patterns 550, 580, 555 and 585 may include a metal nitride, e.g., titanium nitride.

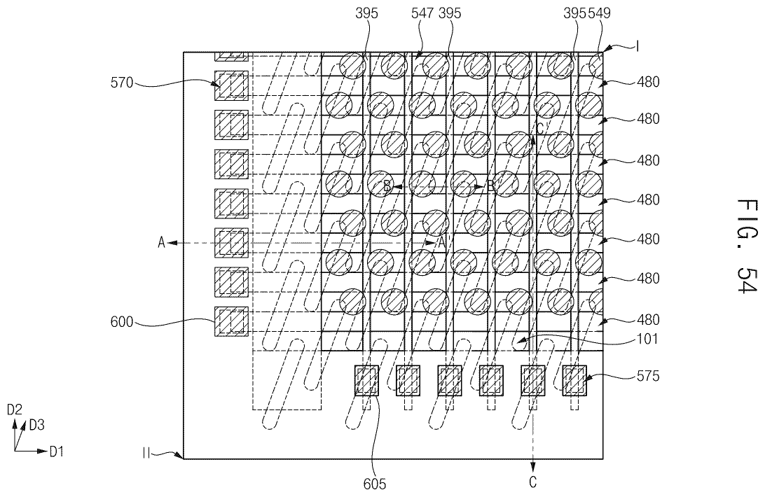

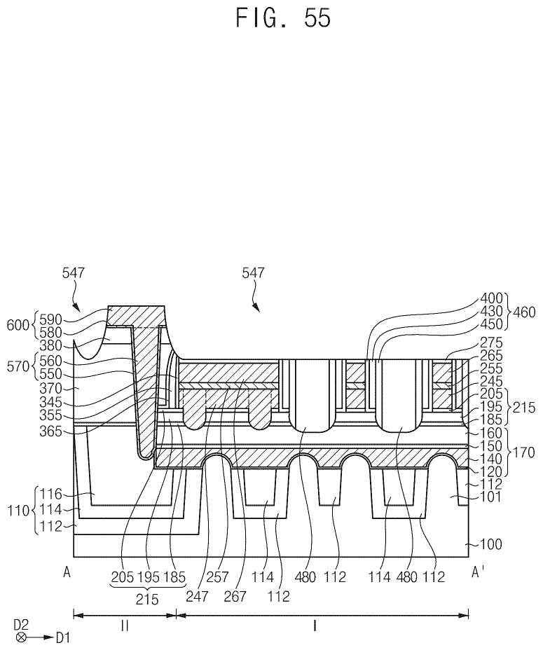

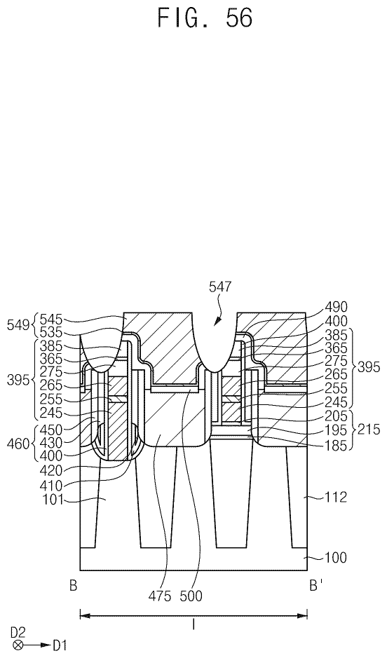

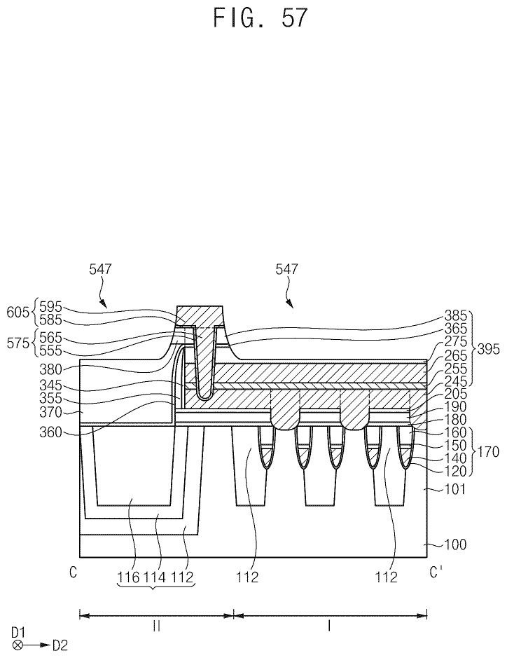

Referring to FIGS. 19 and 20 together with FIGS. 54 to 57, the eleventh insulating interlayer may include a sixth insulation pattern 610 on an inner wall of a fifteenth opening 547, which may extend through the upper contact plug 549, a portion of the insulation structure of the second bit line structure 395 and the dummy bit line structure 397, and portions of the third, fifth and sixth spacers 400, 450 and 490 and surround the upper contact plug 549 in a plan view, and an seventh insulation pattern 620 on the sixth insulation pattern 610 and filling a remaining portion of the fifteenth opening 547. The upper end of the air spacer 435 may be closed by the sixth insulation pattern 610.

The sixth and seventh insulation patterns 610 and 620 may include an insulating nitride, e.g., silicon nitride.

The fourth etch stop layer 630, the second capacitor 670 and the second plate electrode 680 of the third semiconductor device may be substantially the same or similar to the first etch stop layer 1980, the first capacitor 1220 and the first plate electrode 1230 of the first semiconductor device, and thus, repeated explanations are omitted herein.

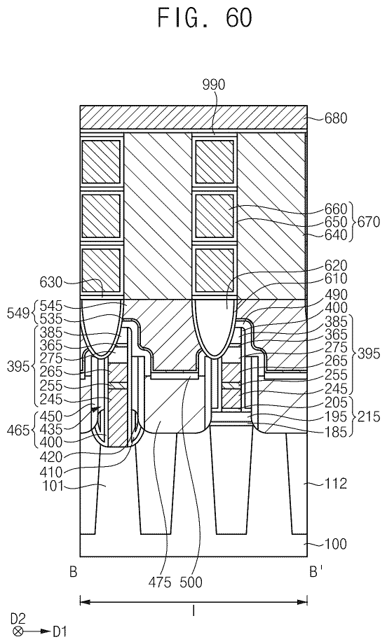

Referring to FIGS. 19 and 20 together with FIG. 60, the second capacitor 670 may be formed on the first region I of the fifth substrate 100, and may include third and fourth capacitor electrodes 640 and 660 and a second dielectric layer 650 respectively corresponding to the first and second capacitor electrodes 1190 and 1210 and the first dielectric layer 1200 of the first capacitor 1220 of the first semiconductor device. The third capacitor electrode 640 may extend through the fourth etch stop layer 630 on the first region I of the fifth substrate 100 to contact an upper surface of the upper contact plug 549.

The twelfth insulating interlayer 700 may cover a sidewall of the second capacitor 670 on the second region II of the fifth substrate 100. The thirteenth insulating interlayer 750, the fourth and fifth bonding layers 760 and 930, and the fifteenth and fourteenth insulating interlayers 920 and 850 may be sequentially stacked on the second plate electrode 680 and the twelfth insulating interlayer 700.

Each of the twelfth, thirteenth, fourteenth, and fifteenth insulating interlayer 700, 750, 850 and 920 may include an oxide, e.g., silicon oxide or a low dielectric material, and each of the fourth and fifth bonding layers 760 and 930 may include, e.g., silicon carbonitride, silicon oxide, etc.

The ninth contact plug 712 may extend through a lower portion of the thirteenth insulating interlayer 750 and the twelfth insulating interlayer 700 to contact a lower surface of the ninth wiring 720 and an upper surface of the seventh wiring 600. The tenth contact plug 714 may extend through the lower portion of the thirteenth insulating interlayer 750 and the twelfth insulating interlayer 700 to contact the lower surface of the ninth wiring 720 and an upper surface of the eighth wiring 605. The eleventh contact plug 716 may extend through the lower portion of the thirteenth insulating interlayer 750 and the twelfth insulating interlayer 700 to contact the lower surface of the ninth wiring 720 and an upper surface of the second plate electrode 680.

The ninth and tenth wirings 720 and 740 may be sequentially stacked in the vertical direction. The third via 730 may partially extend through the thirteenth insulating interlayer 750 to contact an upper surface of the ninth wiring 720 and a lower surface of the tenth wiring 740. In the drawing, the ninth and tenth wiring 720 and 740 are stacked in the vertical direction at two levels within the twelfth insulating interlayer 700, but the concept of the present invention is not limited thereto.

Each of the ninth and tenth wirings 720 and 740, the ninth to eleventh contact plugs 712, 714 and 716 and the third via 730 may include, for example, a metal, a metal nitride, a metal silicide, etc.

The third bonding structure 765 may extend through the fourth bonding layer 760 and an upper portion of the thirteenth insulating interlayer 750 to contact an upper surface of the tenth wiring 740, and the fourth bonding structure 935 may extend through the fifth bonding layer 930 and a lower portion of the fifteenth insulating interlayer 920 to contact an upper surface of the third bonding structure 765 and a lower surface of the thirteenth wiring 910. The third and fourth bonding structures 735 and 935 are substantially the same as or similar to the first and second bonding structures 505 and 725 of the first semiconductor device, and thus, repeated explanations are omitted herein.

The thirteenth, twelfth, and eleventh wirings 910, 890 and 870 may be stacked in the vertical direction on the fifth bonding layer 930. The fourth via 900 may partially extend through the fifteenth insulating interlayer 920 to contact an upper surface of the thirteenth wiring 910 and a lower surface of the twelfth wiring 890. The thirteenth contact plug 880 may partially extend through the fifteenth insulating interlayer 920 to contact an upper surface of the twelfth wiring 890 and a lower surface of the eleventh wiring 870.

In the drawing, thirteenth, twelfth, and eleventh wirings 910, 890 and 870 are stacked in the vertical direction at three levels within the fifteenth insulating interlayer 920, but the concept of the present invention is not limited thereto.

The sixth substrate 800 may include a semiconductor material, e.g., single crystal silicon, single crystal germanium, single crystal silicon-germanium, etc. The sixth substrate 800 may be a portion of a fifth wafer, and the fifth wafer may be a (110) wafer, a (100) wafer, a (320) wafer, a (310) wafer, etc. A direction connecting a geometric center of the fifth wafer and a notch (or a flat) of the fifth wafer (in the case of a (100) wafer, the <100> direction) may be substantially parallel to the second direction D2.

In an example embodiment, the sixth substrate 800 may include single crystal silicon-germanium, and have a crystal orientation where {110} crystal plane is substantially perpendicular to a direction of the current (that is, the first direction D1 and/or the second direction D2) flowing in a fourth channel, which is a portion of the sixth substrate 800 below the fifth gate structure 830. Accordingly, electronic mobility of a core/peri transistor including the fifth gate structure 830 and the second impurity region 840 may increase.

A fifth isolation pattern 805 may be formed at a lower portion of the sixth substrate 800. The fifth isolation pattern 805 may include an oxide, e.g., silicon oxide.

The fifth gate structure 830 may be formed on a lower surface of the sixth substrate 800, and may include a fifth gate insulation pattern 810 and a fifth gate electrode 820 sequentially stacked downwards in the vertical direction. The second impurity region 840 may be formed at a lower portion of the sixth substrate 800 adjacent to the fifth gate structure 830. The fifth gate structure 830 and the second impurity region 840 may collectively form the core/peri transistor. The core/peri transistor of the third semiconductor device may be substantially the same as or similar to the core/peri transistor of the first semiconductor device, and thus, repeated explanations are omitted herein.

The twelfth contact plug 860 may extend through the fourteenth insulating interlayer 850 to contact an upper surface of the eleventh wiring 870 and a lower surface of the second impurity region 840.

Like the first semiconductor device, the third semiconductor device may be manufactured by forming the cell transistor and the core/peri transistor on separate wafers, and then bonding the separate wafers to each other. Accordingly, electrical characteristics of the third semiconductor device may be improved by adjusting crystal orientation of the fifth and sixth substrates 100 and 800 in consideration of the characteristics of each of the cell transistor and the core/peri transistor.

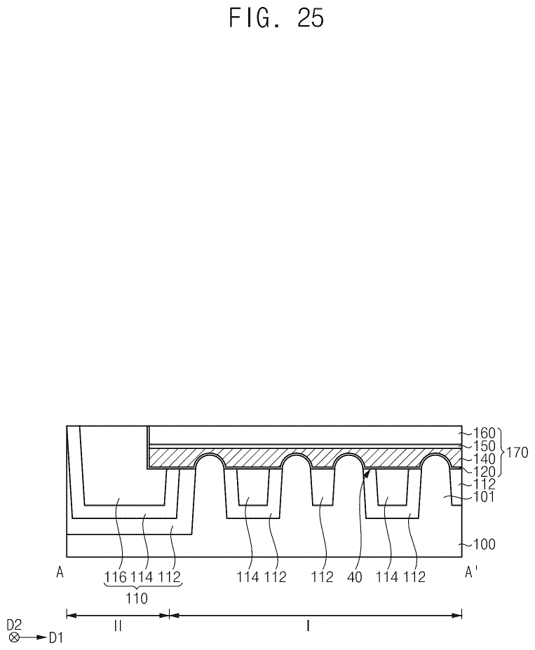

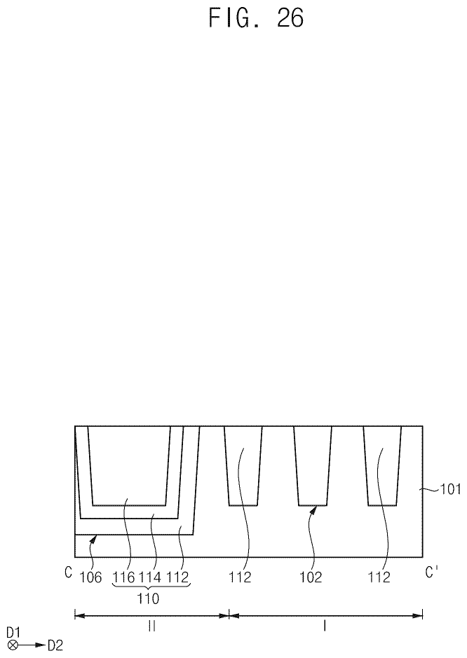

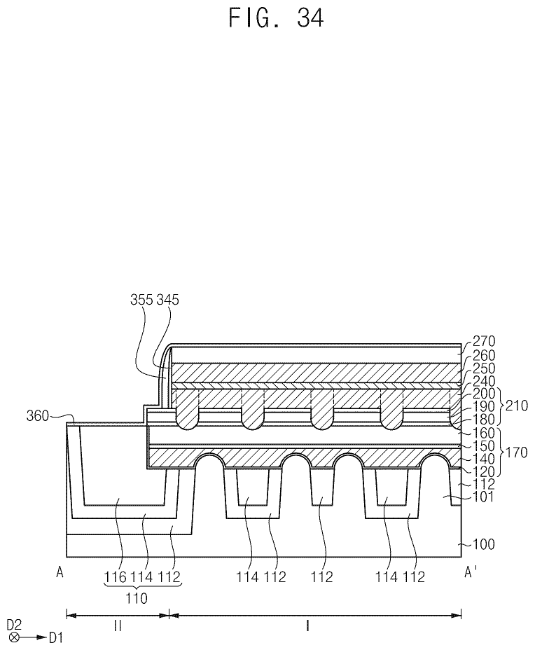

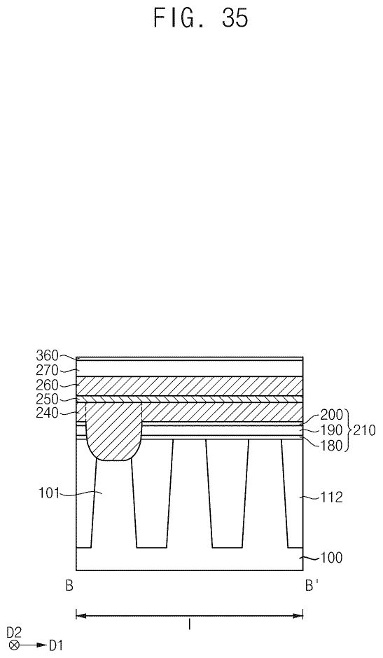

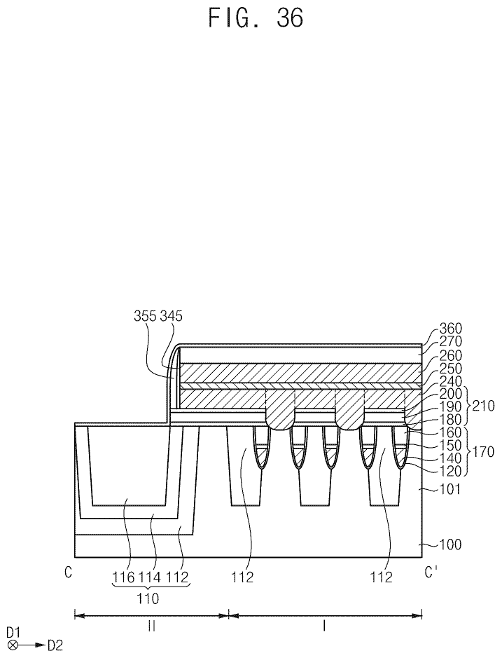

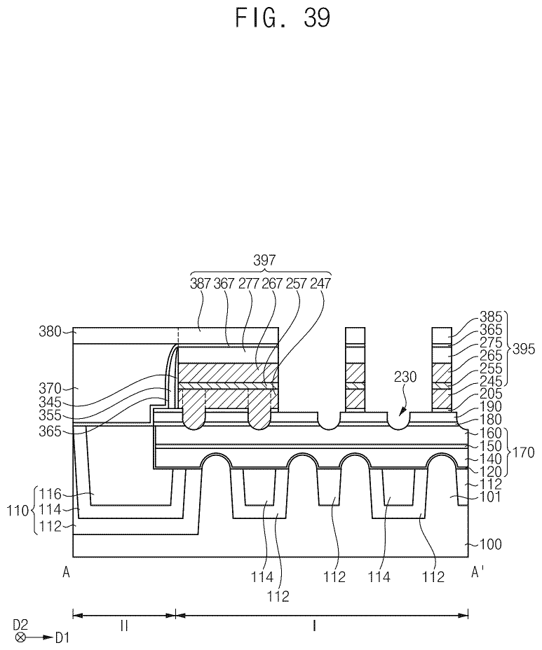

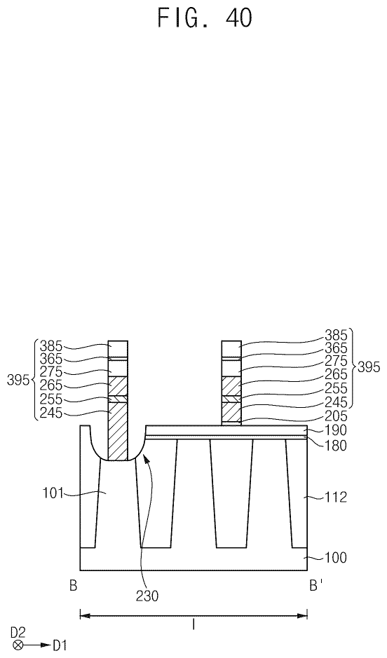

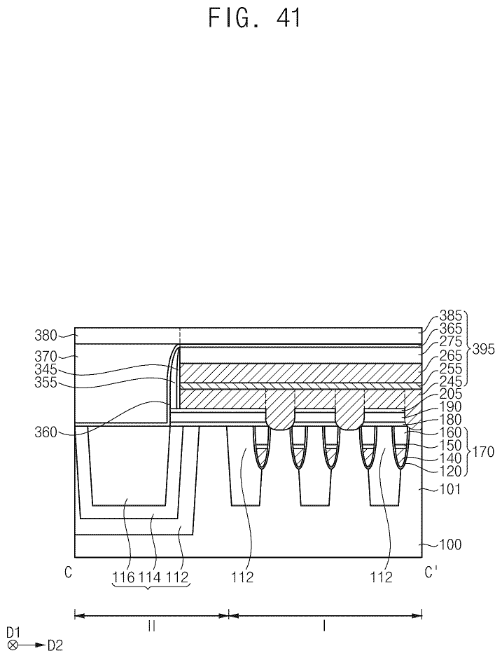

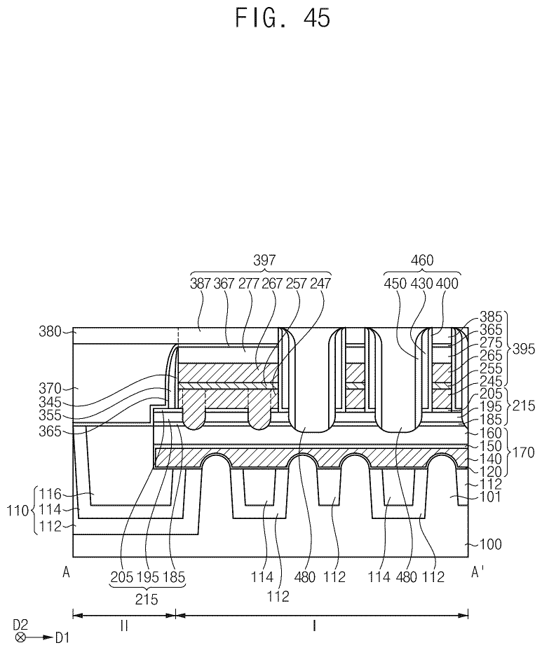

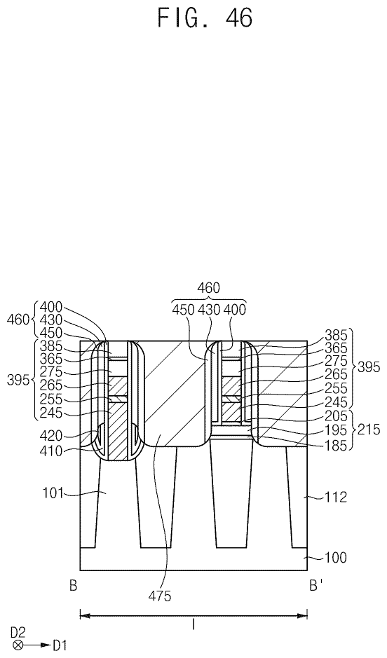

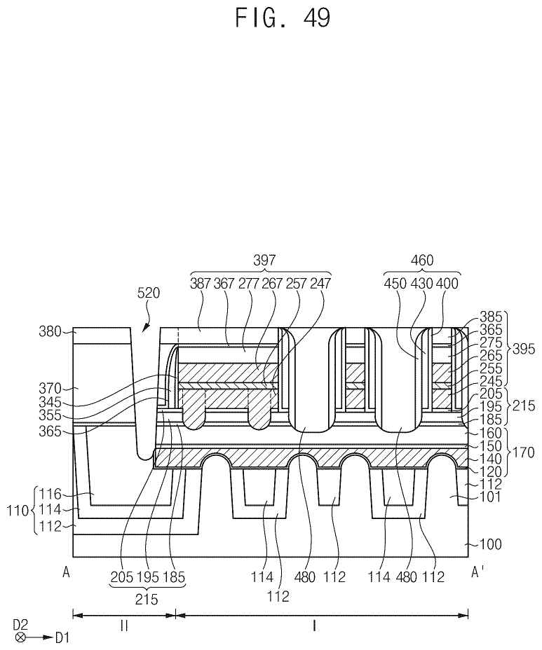

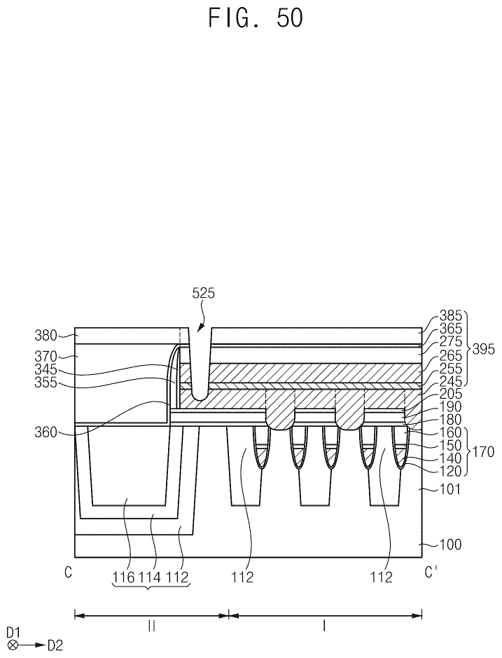

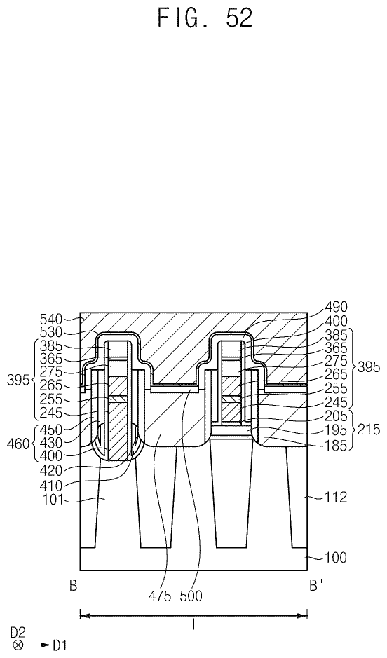

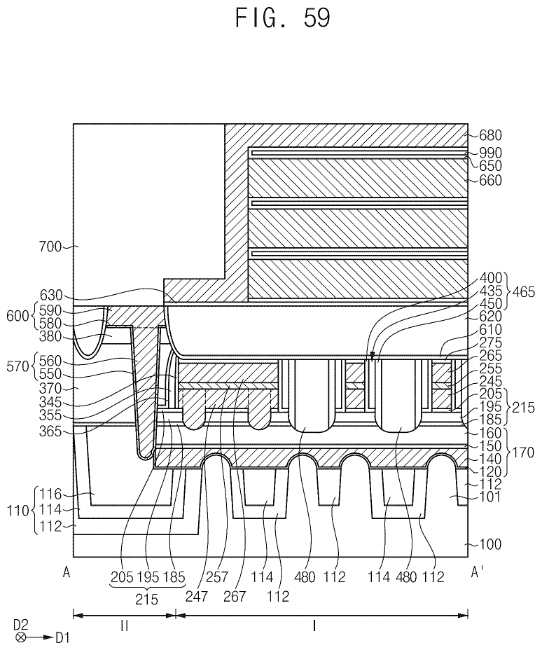

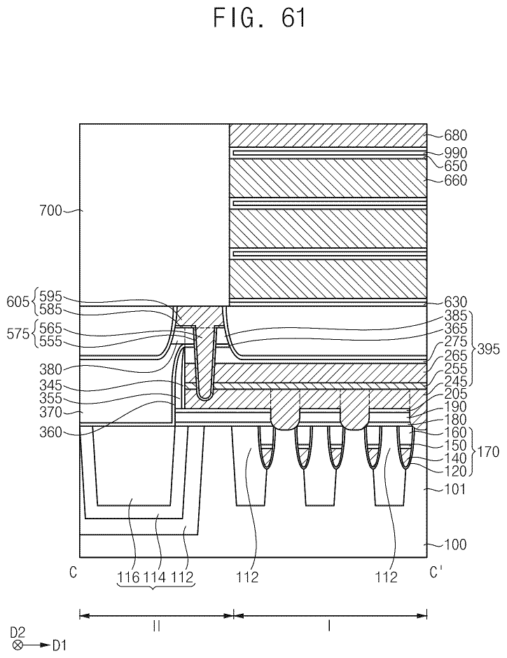

FIGS. 21 to 64 are plan views and cross-sectional views illustrating a method of manufacturing a third semiconductor device according to example embodiments.

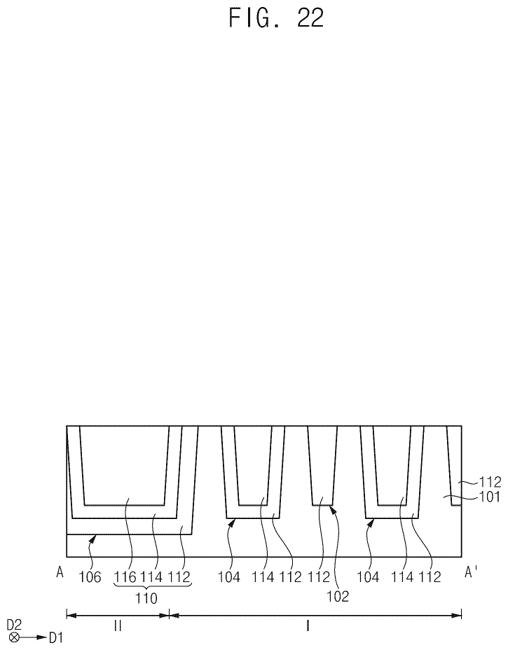

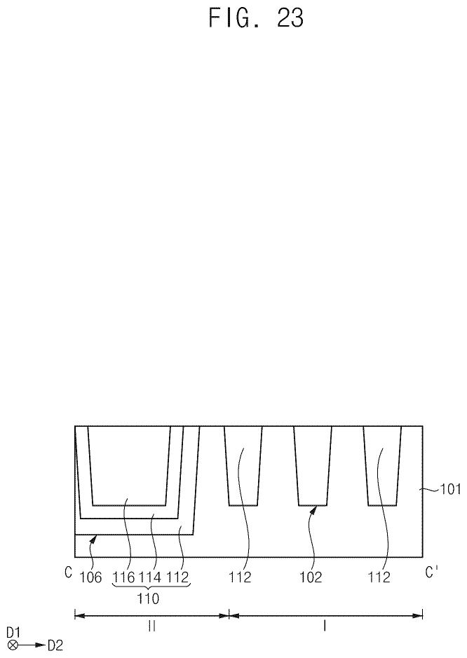

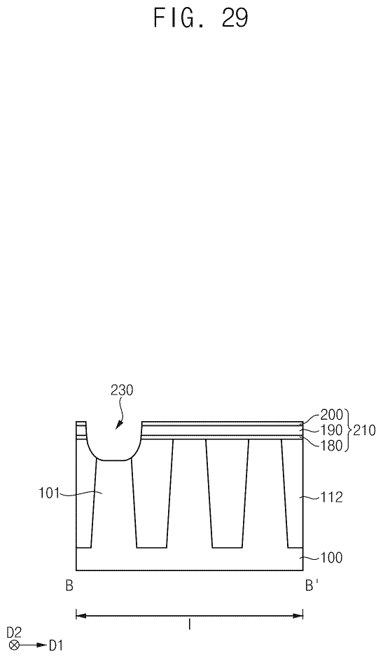

Specifically, FIGS. 21, 24, 27, 33, 38, 44, 48, 54 and 58 are the plan views, FIGS. 22, 25, 28, 31, 34, 37, 39, 42, 45, 49, 51, 55, 59, 62 and 64 are cross-sectional views taken along lines A-A′ of corresponding plan views, respectively, FIGS. 29, 32, 35, 40, 43, 46-47, 52, 56 and 60 are cross-sectional views taken along lines B-B′ of corresponding plan views, respectively, and FIGS. 23, 26, 30, 36, 41, 50, 53, 57, 61 and 63 are cross-sectional views taken along lines C-C′ of corresponding plan views, respectively.

Referring to FIGS. 21 to 23, active patterns 101 may be formed on the fifth substrate 100 including first and second regions I and II.

The active patterns 101 may be formed by removing an upper portion of the fifth substrate 100 to form a recess structure. The active pattern 101 may extend in the third direction D3 on the first region I and the second region II adjacent thereto, and a plurality of active patterns 101 may be spaced apart from each other in each of the first and second directions D1 and D2.

The recess structure may include first, second and third recesses 102, 104 and 106. The first recess 102 may be formed between ones of the active patterns 101 spaced apart from each other by a relatively small distance on the first region I of the fifth substrate 100, the second recess 104 may be formed between ones of the active patterns 101 spaced apart from each other by a relatively large distance on the first region I of the fifth substrate 100, and the third recess 106 may be formed on the second region II of the fifth substrate 100 or between the first and second regions I and II of the fifth substrate 100.

In example embodiments, the third recess 106 may have a width and/or a depth greater than a width and/or a depth of the second recess 104, and the second recess 104 may have a width and/or a depth greater than a width and/or a depth of the first recess 102.

An isolation structure 110 may be formed to cover sidewalls of the active patterns 101.

Referring to FIGS. 24 to 26, an etching process may be performed on the active pattern 101 and the isolation structure 110 on the first region I of the fifth substrate 100 and the second region II of the fifth substrate 100 adjacent to the first region I of the fifth substrate 100 to form a fourth recess 40.

In example embodiments, during the etching process, the active pattern 101 including a semiconductor material may be less etched than the isolation structure 110 including an insulating material due to the etching selectivity. Thus, the fourth recess 40 may have a concave upper surface on an upper surface of the active pattern 101.

A fourth gate insulation layer and a third conductive layer may be sequentially stacked on an inner wall of the fourth recess 40 and upper surfaces of the active patterns 101 and the isolation structure 110, the fourth gate insulation layer and the third conductive layer may be planarized until the upper surfaces of the active patterns 101 and the isolation structure 110 are exposed, and an upper portion of the third conductive layer may be removed by, e.g., an etch back process.

The planarization process may include a chemical mechanical polishing (CMP) process and/or an etch back process.

By the planarization process, a fourth gate insulation pattern 120 may be formed on the inner wall of the fourth recess 40, and by the etch back process, a third conductive pattern 140 may be formed on the fourth gate insulation pattern 120 to fill a lower portion of the fourth recess 40.

A fourth conductive pattern 150 may be formed on the third conductive pattern 140. A fifth gate mask layer may be formed on the fourth conductive pattern 150, the active patterns 101 and the isolation structure 110 to fill the fourth recess 40. The fifth gate mask layer may be planarized until the upper surfaces of the active patterns 101 and the isolation structure 110 are exposed, so that a fifth gate mask 160 may be formed to fill an upper portion of the fourth recess 40. The third conductive pattern 140 and the fourth conductive pattern 150 may collectively form a fourth gate electrode, and a first barrier pattern may be further formed between the fourth gate insulation pattern 120 and the third conductive pattern 140.

The fourth gate insulation pattern 120, the first barrier pattern, the third conductive pattern 140, the fourth conductive pattern 150 and the fifth gate mask 160 may collectively form a fourth gate structure 170. In example embodiments, the fourth gate structure 170 may extend in the first direction D1 on the first region I of the fifth substrate 100 and the second region II of the fifth substrate 100 adjacent to the first region I of the fifth substrate 100 in the first direction D1, and a plurality of fourth gate structures 170 may be spaced apart from each other in the second direction D2.

Referring to FIGS. 27 to 30, an insulation layer structure 210 may be formed on the first and second regions I and II of the fifth substrate 100, a portion of the insulation layer structure 210 on the second region II of the fifth substrate 100 except for the second region II of the fifth substrate 100 adjacent to the first region I of the fifth substrate 100 may be removed.

The insulation layer structure 210 may be patterned, and the active pattern 101, the isolation structure 110, and the fifth gate mask 160 of the fourth gate structure 170 may be partially etched using the patterned insulation layer structure 210 as an etching mask to form a seventh opening 230. In example embodiments, the patterned insulation layer structure 210 may have a shape of a circle or an ellipse in a plan view, and a plurality of insulation layer structures 210 may be spaced apart from each other in the first and second directions D1 and D2 on the first region I of the fifth substrate 100 and the second region II of the fifth substrate 100 adjacent to the first region I of the fifth substrate 100. Each of the insulation layer structures 210 may overlap opposite end portions in the third direction D3 of the active patterns 101 in the vertical direction.

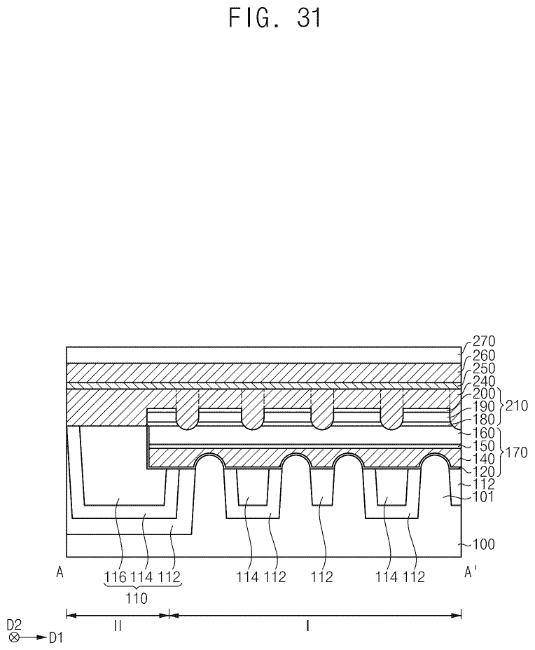

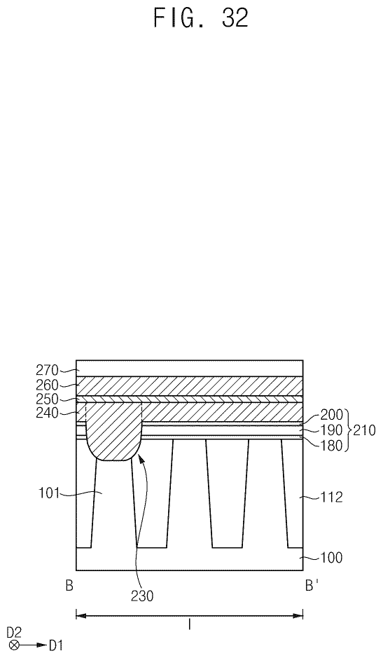

Referring to FIGS. 31 and 32, a fifth conductive layer 240, a second barrier layer 250, a sixth conductive layer 260 and a second mask layer 270 may be sequentially stacked on the insulation layer structure 210, the upper surfaces of the active pattern 101, the isolation structure 110 and the fourth gate structure 170 exposed by the seventh opening 230 on the first region I of the fifth substrate 100, and the isolation structure 110 on the second region II of the fifth substrate 100, which may collectively form a conductive structure layer. The fifth conductive layer 240 may fill the seventh opening 230.

The fifth conductive layer 240 may include doped polysilicon, the second barrier layer 250 may include a metal silicon nitride, e.g., titanium silicon nitride, the sixth conductive layer 260 may include a metal, e.g., tungsten, and the second mask layer 270 may include a nitride, e.g., silicon nitride.

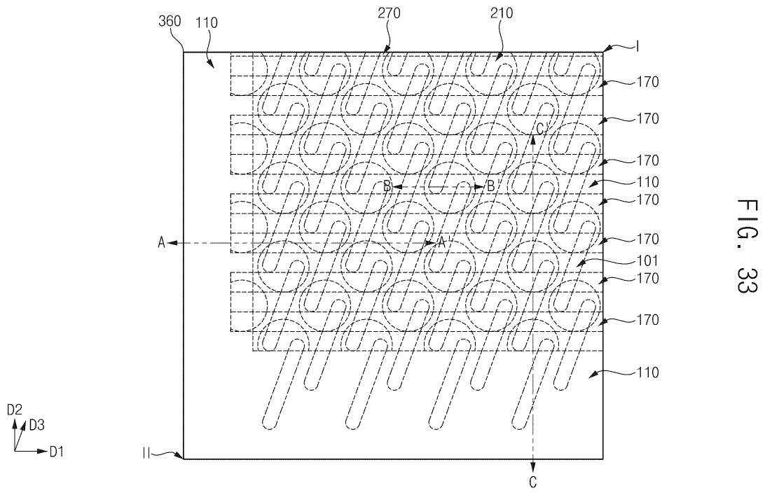

Referring to FIGS. 33 to 36, a portion of the conductive structure layer on the second region II of the fifth substrate 100 may be removed, and thus the insulation layer structure 210 on the second region II of the fifth substrate 100 adjacent to the first region I of the fifth substrate 100, and the upper surfaces of the active pattern 101, the isolation structure 110 and the fourth gate structure 170 exposed by the seventh opening 230 may also be partially exposed.

A first spacer structure may be formed on a sidewall of the conductive structure layer remaining on the first region I of the fifth substrate 100. The first spacer structure may include first and second spacers 345 and 355 stacked on the sidewall of the conductive structure layer in the horizontal direction.

The first spacer 345 may be formed by forming a first spacer layer on the fifth substrate 100 to cover the conductive structure layer and anisotropically etching the first spacer layer. The second spacer 355 may be formed by forming a second spacer layer on the fifth substrate 100 to cover the conductive structure layer and the first spacer 345 and anisotropically etching the second spacer layer.

A second etch stop layer 360 may be formed on the fifth substrate 100 to cover the conductive structure layer, the first spacer structure and the isolation structure 110. The second etch stop layer 360 may include a nitride, e.g., silicon nitride.

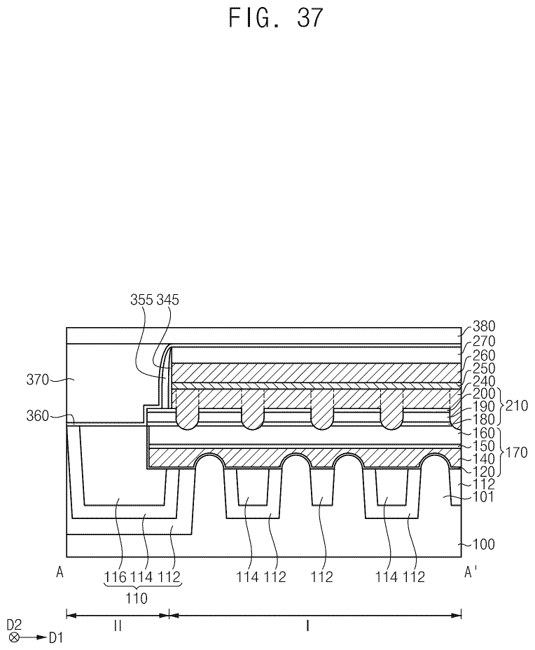

Referring to FIG. 37, a tenth insulating interlayer 370 may be formed on the second etch stop layer 360 to a sufficient height, the tenth insulating interlayer 370 may be planarized until an upper surface of a portion of the second etch stop layer 360 on the conductive structure layer are exposed, and a capping layer 380 may be formed on the tenth insulating interlayer 370 and the second etch stop layer 360.

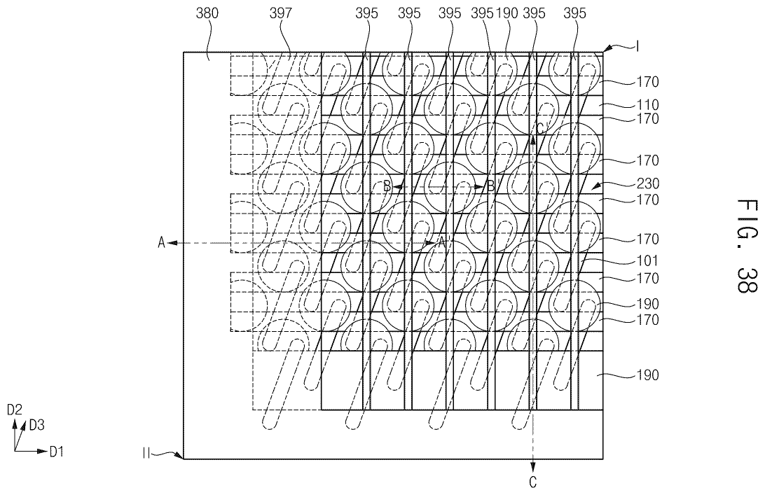

Referring to FIGS. 38 to 41, a portion of the capping layer 380 on the first region I of the fifth substrate 100 and the second region II of the fifth substrate 100 adjacent thereto may be etched to form a first capping pattern 385, and the second etch stop layer 360, the second mask layer 270, the sixth conductive layer 260, the second barrier layer 250 and the fifth conductive layer 240 may be sequentially etched using the first capping pattern 385 as an etching mask.

In example embodiments, the first capping pattern 385 may extend in the second direction D2 on the first region I of the fifth substrate 100 and the second region II of the fifth substrate 100 adjacent thereto in the second direction D2, and a plurality of first capping patterns 385 may be formed to be spaced apart from each other in the first direction D1. The capping layer 380 may remain on the second region II of the fifth substrate 100.

By the etching process, on the first region I of the fifth substrate 100 and the second region II of the fifth substrate 100 adjacent thereto in the second direction D2, a fifth conductive pattern 245, a second barrier pattern 255, a sixth conductive pattern 265, a second mask 275, a second etch stop pattern 365 and the first capping pattern 385 may be sequentially stacked on the seventh opening 230, and a third insulation pattern 205, the fifth conductive pattern 245, the second barrier pattern 255, the sixth conductive pattern 265, the second mask 275, the second etch stop pattern 365 and the first capping pattern 385 may be sequentially stacked on the second insulation layer 190 of the insulation layer structure 210 at an outside of the seventh opening 230.

Hereinafter, the fifth conductive pattern 245, the second barrier pattern 255, the sixth conductive pattern 265, the second mask 275, the second etch stop pattern 365 and the first capping pattern 385 sequentially stacked may be referred to as a second bit line structure 395. In example embodiments, the second bit line structure 395 may extend in the second direction D2 on the first region I of the fifth substrate 100 and the second region II of the fifth substrate 100 adjacent thereto in the second direction D2, and a plurality of bit line structures 395 may be spaced apart from each other in the first direction D1.

A dummy bit line structure 397 including a seventh conductive pattern 247, a third barrier pattern 257, an eighth conductive pattern 267, a third mask 277, a third etch stop pattern 367 and a second capping pattern 387 sequentially stacked and extending in the second direction D2 may be formed on the first region I of the fifth substrate 100 adjacent to the second region II of the fifth substrate 100 in the first direction D1, and the second etch stop layer 360 may remain on the first spacer structure, a portion of the insulation layer structure 210 and the isolation structure 110. Additionally, the capping layer 380 may remain on the tenth insulating interlayer 370.

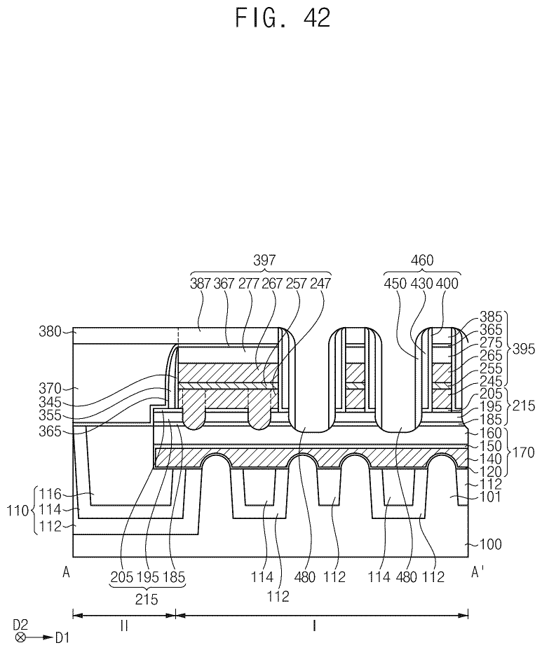

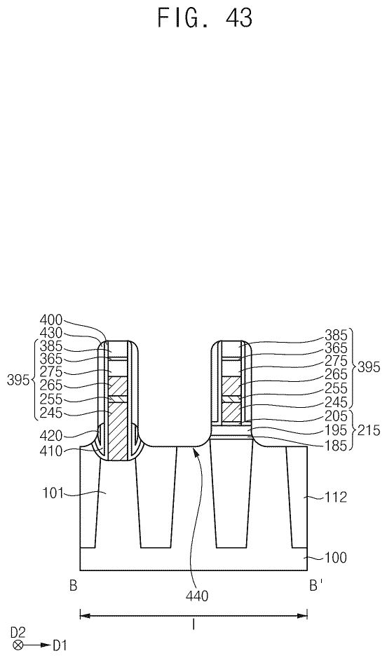

Referring to FIGS. 42 and 43, a third spacer layer may be formed on the fifth substrate 100 to cover the second bit line structure 395, the dummy bit line structure 397 and the capping layer 380, and fourth and fifth insulation layers may be sequentially formed on the fifth spacer layer.

The third spacer layer may also cover a sidewall of the third insulation pattern 205 between the second insulation layer 190 and the second bit line structure 395, and the fifth insulation layer may fill the seventh opening 230.

The third spacer layer may include a nitride, e.g., silicon nitride, the fourth insulation layer may include an oxide, e.g., silicon oxide, and the fifth insulation layer may include a nitride, e.g., silicon nitride.

The fourth and fifth insulation layers may be etched by an etching process. In example embodiments, the etching process may be performed by a wet etch process using an etching solution including phosphorous acid (H₃PO₄), SCl, hydrogen fluoride (HF), and other portions of the fourth and fifth insulation layers except for a portion in the seventh opening 230 may be removed. Thus, most of an entire surface of the third spacer layer, that is, an entire surface except for a portion thereof in the seventh opening 230 may be exposed, and portions of the fourth and fifth insulation layers remaining in the seventh opening 230 may form fourth and fifth insulation patterns 410 and 420, respectively.

A fourth spacer layer may be formed on the exposed surface of the third spacer layer and the fourth and fifth insulation patterns 410 and 420 in the seventh opening 230, and may be anisotropically etched to form a fourth spacer 430 on the surface of the third spacer layer and the fourth and fifth insulation patterns 410 and 420 to cover a sidewall of the second bit line structure 395. The fourth spacer 430 may also be formed on a sidewall of the dummy bit line structure 397. The fourth spacer 430 may include an oxide, e.g., silicon oxide.

A dry etching process may be performed to form an eighth opening 440 exposing the upper surface of the active pattern 101. An upper surface of the isolation structure 110 and an upper surface of the fifth gate mask 160 may also be exposed by the eighth opening 440.

By the dry etching process, portions of the third spacer layer on upper surfaces of the first and second capping patterns 385 and 387, the second insulation layer 190 and the capping layer 380 may be removed, and thus a third spacer 400 covering the sidewall of the second bit line structure 395 may be formed. The third spacer 400 may also cover the sidewall of the dummy bit line structure 397.

Additionally, during the dry etching process, the first and second insulation layers 180 and 190 may be partially removed, such that first and second insulation patterns 185 and 195 may remain under the second bit line structure 395. The first to third insulation patterns 185, 195 and 205 that are sequentially stacked under the second bit line structure 395 may collectively form an insulation pattern structure 215.

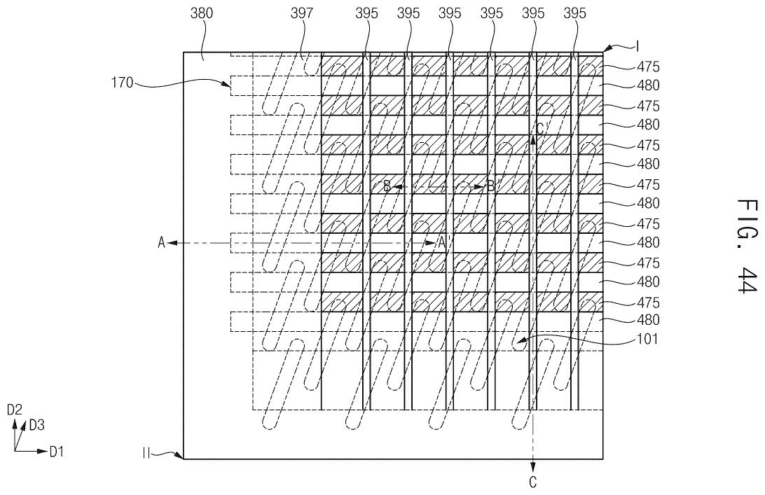

Referring to FIGS. 44 to 46, a fifth spacer layer may be formed on the upper surface of the first and second capping patterns 385 and 387, the upper surface of the capping layer 380, an outer sidewall of the fourth spacer 430, portions of upper surfaces of the fourth and fifth insulation patterns 410 and 420, and the upper surfaces of the active pattern 101, the isolation structure 110 and the fifth gate mask 160 exposed by the eighth opening 440, and the fifth spacer layer may be anisotropically etched to form a fifth spacer 450 covering an outer sidewall of fourth spacer 430 on the sidewalls of the second bit line structure 395 and the dummy bit line structure 397. The fifth spacer 450 may include a nitride, e.g., silicon nitride.

The third to fifth spacers 400, 430 and 450 sequentially stacked in the horizontal direction from the sidewall of the second bit line structure 395 on the first region I of the fifth substrate 100 may be referred to as a preliminary second spacer structure 460.

A lower contact plug layer may be formed on the first region I of the fifth substrate 100 to fill the eighth opening 440, and the lower contact plug layer may be planarized until the upper surfaces of the capping layer 380 and the first and second capping patterns 385 and 387 are exposed.

The lower contact plug layer may extend in the second direction D2 between neighboring ones of the second bit line structures 395 in the first direction D1 and between the second bit line structure 395 and the dummy bit line structure 397 on the first region I of the fifth substrate 100, and a plurality of lower contact plug layers may be spaced apart from each other in the first direction D1. Each of the lower contact plug layers may contact an upper surface of an end portion in the third direction D3 of the active pattern 101 extending in the third direction D3.

An etching mask having ninth openings, each of which may extend in the first direction D1, spaced apart from each other in the second direction D2 may be formed on the capping layer 380, the second bit line structure 395, the dummy bit line structure and the lower contact plug layer, and an etching process may be performed on the lower contact plug layer using the etching mask to form a tenth opening 445.

In example embodiments, the ninth opening may overlap the fourth gate structure 170 in the vertical direction, and the tenth opening 445 may expose an upper surface of the fifth gate mask 160 of the fourth gate structure 170. As the tenth opening 445 is formed, the lower contact plug layer extending in the second direction D2 may be divided into a plurality of lower contact plugs 475 spaced apart from each other in the second direction D2.

After removing the etching mask, a fence pattern 480 may be formed to fill the tenth opening 445. A plurality of fence patterns 480 may be spaced apart from each other in the second direction D2 between the second bit line structures 395 and between the second bit line structure 395 and the dummy bit line structure 397. The fence pattern 480 may include a nitride, e.g., silicon nitride.

As illustrated above, the lower contact plugs 475 and the fence patterns 480 that may be alternately and repeatedly arranged in the second direction D2 may be formed by forming the lower contact plug layer extending in the second direction D2 between the second bit line structures 395, planarizing the lower contact plug layer, forming the tenth openings 445 through the lower contact plug layer, and filling the tenth opening 445 by the fence pattern 480, however, the inventive concept may not be limited thereto.

Alternatively, the lower contact plugs 475 and the fence patterns 480 that may be alternately and repeatedly arranged in the second direction D2 may be formed by forming a fence layer extending in the second direction D2 between the second bit line structures 395, forming eleventh openings through the fence layer spaced apart from each other in the second direction D2 to divide the fence layer into the fence patterns 480, forming the lower contact plug layer on the fence layer to fill the eleventh openings, planarizing the lower contact plug layer to form the lower contact plugs 475.

Alternatively, the lower contact plugs 475 and the fence patterns 480 that may be alternately and repeatedly arranged in the second direction D2 may be formed by forming a sacrificial layer including an oxide, e.g., silicon oxide and extending in the second direction D2 between the second bit line structures 395, forming the fence patterns 480 through the sacrificial layer spaced apart from each other in the second direction D2, removing the sacrificial layer to form twelfth openings, forming the lower contact plug layer to fill the twelfth openings, and planarizing the lower contact plug layer to form the lower contact plugs 475.

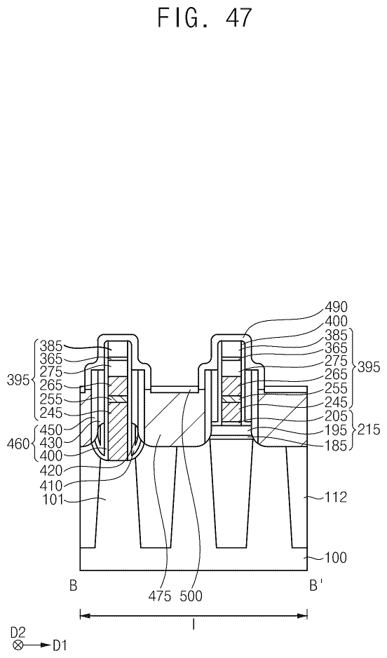

Referring to FIG. 47, an upper portion of the lower contact plug 475 may be removed to expose an upper portion of the preliminary second spacer structure 460 on the sidewalls of the second bit line structure 395 and the dummy bit line structure 397, and upper portions of the fourth and fifth spacers 430 and 450 of the exposed preliminary second spacer structure 460 may be removed.

An etch back process may be further performed to remove an upper portion of the lower contact plug 475. Thus, an upper surface of the lower contact plug 475 may be lower than uppermost surfaces of the fourth and fifth spacers 430 and 450.

An sixth spacer layer may be formed on the second bit line structure 395, the dummy bit line structure 397, the preliminary second spacer structure 460, the fence pattern 480, the capping layer 380, and the lower contact plug 475, and may be anisotropically etched so that an sixth spacer 490 may be formed to cover the preliminary second spacer structure 460 on each of opposite sidewalls of the second bit line structure 395 in the first direction D1 and that an upper surface of the lower contact plug 475 may not be covered to be exposed.

An ohmic contact pattern 500 may be formed on the exposed upper surface of the lower contact plug 475. In example embodiments, the ohmic contact patterns 500 may be formed by forming a first metal layer on the first and second capping patterns 385 and 387, the capping layer 380, the fence pattern 480, the sixth spacer 490, and the lower contact plug 475, thermally treating the first metal layer, and removing an unreacted portion of the first metal layer. The ohmic contact patterns 500 may include a metal silicide, e.g., cobalt silicide, nickel silicide, titanium silicide, etc.

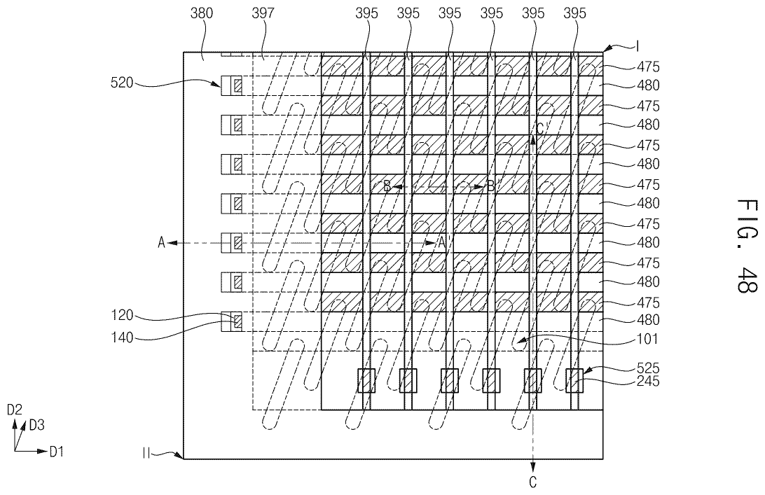

Referring to FIGS. 48 to 50, a thirteenth opening 520 may be formed through a portion of the capping layer 380 on the portion of the second region II of the fifth substrate 100 adjacent to the first region I of the fifth substrate 100 in the first direction D1, and the tenth insulating interlayer 370, the second etch stop layer 360, the insulation pattern structure 215, the isolation structure 110, the fifth gate mask 160 and the fourth conductive pattern 150 to expose the third conductive pattern 140. The thirteenth opening 520 may also expose the fourth gate insulation pattern 120 on the sidewall of the third conductive pattern 140.

In addition, a fourteenth opening 525 may be formed through a portion of the capping layer 380 on the portion of the second region II of the fifth substrate 100 adjacent to the first region I of the fifth substrate 100 in the second direction D2, and the second etch stop layer 360, the second mask 275, the sixth conductive pattern 265 and the second barrier pattern 255 to expose the fifth conductive pattern 245.

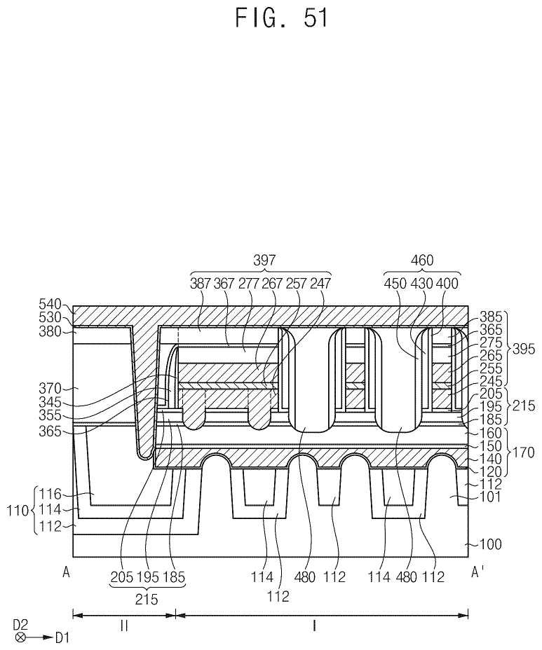

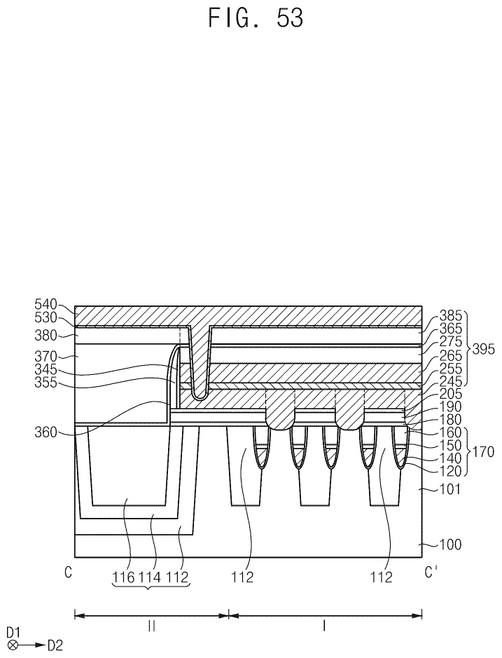

Referring to FIGS. 51 and 53, a fourth barrier layer 530 may be formed on the first and second capping patterns 385 and 387, the fence pattern 480, the sixth spacer 490, the ohmic contact pattern 500 and the lower contact plug 475 on the first region I of the fifth substrate 100, the capping layer 380, a sidewall of the thirteenth opening 520, the third conductive pattern 140, the fourth gate insulation pattern 120 and the isolation structure 110 exposed by the thirteenth opening 520, a sidewall of the fourteenth opening 525, and the fifth conductive pattern 245 exposed by the fourteenth opening 525 on the second region II of the fifth substrate 100. A second metal layer 540 may be formed on the fourth barrier layer 530 to fill a space between the second bit line structures 395, between the second bit line structure 395 and the dummy bit line structure 397, and the thirteenth and fourteenth openings 520 and 525.

Referring to FIGS. 54 to 57, the second metal layer 540 and the fourth barrier layer 530 may be patterned.

Thus, an upper contact plug 549 may be formed on the first region I of the fifth substrate 100. Additionally, a seventh wiring 600 may be formed on the second region II of the fifth substrate 100 adjacent to the first region I of the fifth substrate 100 in the first direction D1, and an eighth wiring 605 may be formed on the second region II of the fifth substrate 100 adjacent to the first region I of the fifth substrate 100 in the second direction D2. A fifteenth opening 547 may be formed between the upper contact plug 549 and the seventh and eighth wirings 600 and 605.

The fifteenth opening 547 may be formed by removing not only the second metal layer 540 and the fourth barrier layer 530 but also the first and second capping patterns 385 and 387, the fence pattern 480, the capping layer 380, the preliminary second spacer structure 460, the sixth spacer 490, the second etch stop layer 360, the second etch stop pattern 365, and the second mask 275 to expose the upper surface of the fourth spacer 430.

As the fifteenth opening 547 is formed, the second metal layer 540 and the fourth barrier layer 530 may be transformed into a first metal pattern 545 and a fourth barrier pattern 535, respectively, covering a lower surface of the first metal pattern 545, which may collectively form an upper contact plug 549 on the first region I of the fifth substrate 100. In example embodiments, a plurality of upper contact plugs 549 may be formed to be spaced apart from each other in each of the first and second directions D1 and D2, and may be arranged in a honeycomb pattern or a lattice pattern in a plan view. Each of the upper contact plugs 549 may have a shape of a circle, an ellipse, or a polygon in a plan view.

The lower contact plug 475, the ohmic contact pattern 500 and the upper contact plug 549 sequentially stacked on the first region I of the fifth substrate 100 may collectively form a sixth contact plug structure.

The seventh wiring 600 may include a third metal pattern 590 and a sixth barrier pattern 580 covering a lower surface of the third metal pattern 590, and a seventh contact plug 570 including a second metal pattern 560 and a fifth barrier pattern 550 may be formed in the thirteenth opening 520. The eighth wiring 605 may include a fifth metal pattern 595 and an eighth barrier pattern 585 covering a lower surface of the fifth metal pattern 595, and an eighth contact plug 575 including a fourth metal pattern 565 and a seventh barrier pattern 555 may be formed in the fourteenth opening 525.

In example embodiments, the seventh wiring 600 may overlap the thirteenth opening 520 in the vertical direction, and a plurality of seventh wirings 600 may be spaced apart from each other in the second direction D2. The seventh wiring 600 may be electrically connected to the third conductive pattern 140 through the seventh contact plug 570, and thus may apply electrical signal to the fourth gate structure 170.

In example embodiments, the eighth wiring 605 may overlap the fourteenth opening 525 in the vertical direction, and a plurality of eighth wirings 605 may be spaced apart from each other in the first direction D1. The eight wiring 605 may be electrically connected to the fifth conductive pattern 245 through the eighth contact plug 575, and thus may apply electrical signal to the second bit line structure 395.

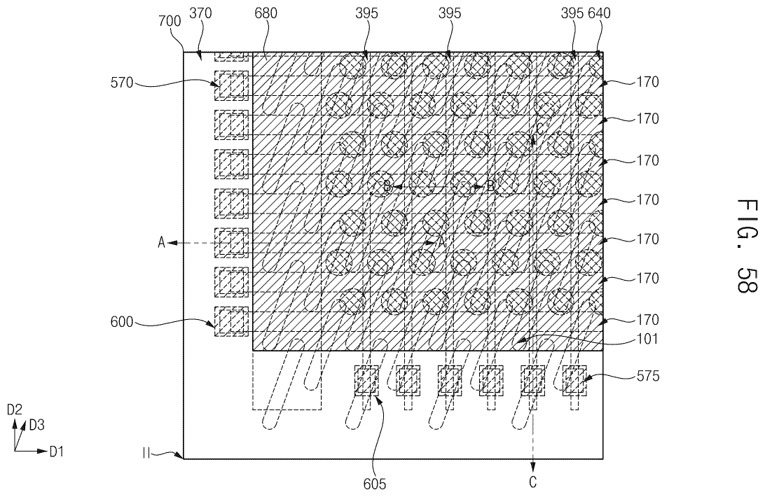

Referring to FIGS. 58 to 61, the exposed fourth spacer 430 may be removed to form an air gap 435 connected to the fifteenth opening 547. The fourth spacer 430 may be removed by, e.g., a wet etching process.

In example embodiments, not only a first portion of the fourth spacer 430 on the sidewalls of the second bit line structure 395 and the dummy bit line structure 397, which is directly exposed by the fifteenth opening 547, but also a second portion of the fourth spacer 430, which is parallel to the first portion in the horizontal direction, may be removed. That is, not only a portion of the fourth spacer 430 exposed by the fifteenth opening 547 not to be covered by the upper contact plug 549 but also a portion of the fourth spacer 430 covered by the upper contact plug 549 may be removed.

An eleventh insulating interlayer may be formed to fill the fifteenth opening 547.

In example embodiments, the eleventh insulating interlayer may include sixth and seventh insulation layers 610 and 620 sequentially stacked. The sixth insulation layer 610 may include a material having a poor gap filling characteristic, and thus the air gap 435 may not be filled with the sixth insulation layer 610, but may remain, which may be referred to as an air spacer 435. The third and fifth spacers 400 and 450 and the air spacer 435 may collectively form a second spacer structure 465. The air spacer 435 may be a spacer including an air. The seventh insulation layer 620 may include an oxide, e.g., silicon oxide or a nitride, e.g., a silicon nitride.

A second capacitor 670 contacting an upper surface of the upper contact plug 549, and a second plate electrode 680 may be formed. The second capacitor 670 and the second plate electrode 680 of the third semiconductor device may be formed by performing processes substantially the same or similar to those of forming the first capacitor 220 and the first plate electrode 1230 of the first semiconductor device.

A twelfth insulating interlayer 700 may be formed to on the second plate electrode 680, the seventh and eighth wirings 600 and 605 and the eleventh insulating interlayer to a sufficient height, and the twelfth insulating interlayer 700 may be planarized until an upper surface of the second plate electrode 680 is exposed.

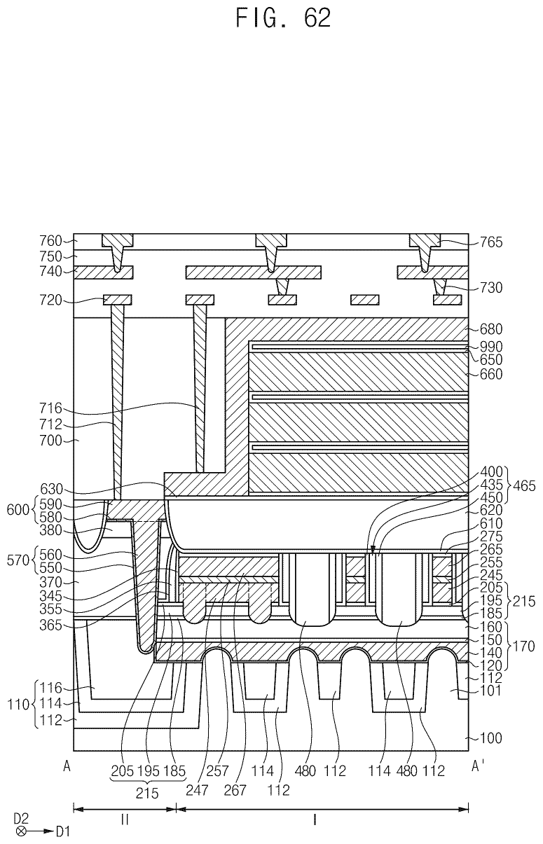

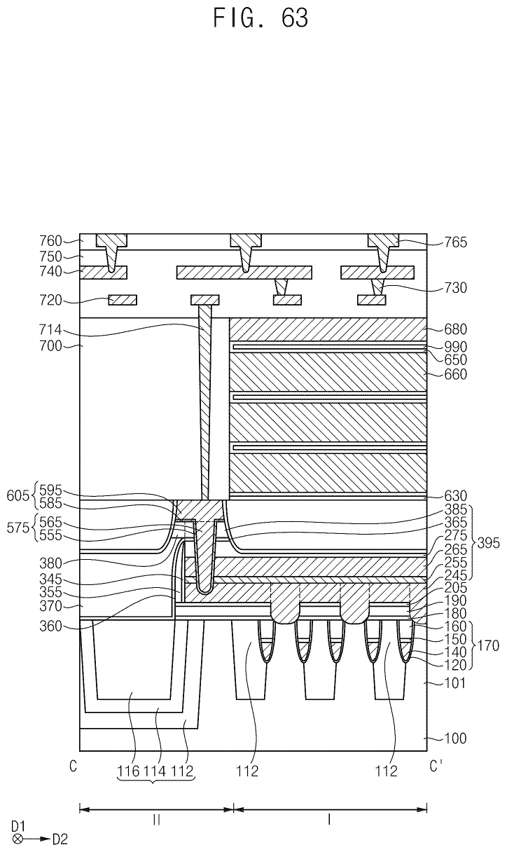

Referring to FIGS. 62 and 63, ninth to eleventh contact plugs 712, 714 and 716, ninth and tenth wirings 720 and 740 and a third via 730 may be formed on the twelfth insulating interlayer 700 and the second plate electrode 680, and a thirteenth insulating interlayer 750 may be formed to cover the ninth to eleventh contact plugs 712, 714 and 716, the ninth and tenth wirings 720 and 740 and the third via 730.

A fourth bonding layer 760 and a third bonding structure 765 extending through the fourth bonding layer 760 may be formed on the thirteenth insulating interlayer 750. In example embodiments, the third bonding structure 765 may include a third bonding contact pattern extending through a lower portion of the fourth bonding layer 760 and an upper portion of the thirteenth insulating interlayer 750 to contact an upper surface of the tenth wiring 740, and a third bonding pad extending through an upper portion of the fourth bonding layer 760 to contact an upper surface of the third bonding contact pattern.

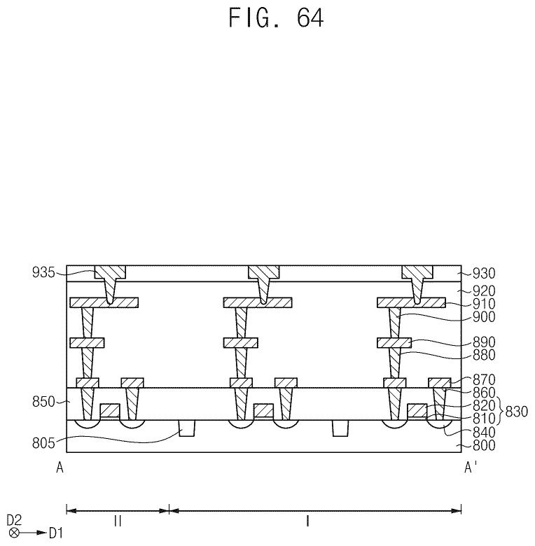

Referring to FIG. 64, a fifth isolation pattern 805 may be formed on an upper portion of the sixth substrate 800.

A fifth gate structure 830 may be formed on the sixth substrate 800, and a second impurity region 840 may be formed at an upper portion of the sixth substrate 800 adjacent thereto, thereby forming a core/peri transistor including the fifth gate structure 830 and the second impurity region 840.

A fourteenth insulating interlayer 850 may be formed on the sixth substrate 800 to cover the core/peri transistor, and a twelfth contact plug 860 may be formed through the fourteenth insulating interlayer 850 to contact an upper surface of the second impurity region 840.

Eleventh to thirteenth wirings 870, 890 and 910, a thirteenth contact plug 880 and a fourth via 900 may be formed on the fourteenth insulating interlayer 850, and a fifteenth insulating interlayer 920 may be formed to cover the eleventh to thirteenth wirings 870, 890 and 910, the thirteenth contact plug 880 and the fourth via 900.

A fifth bonding layer 930 and a fourth bonding structure 935 extending through the fifth bonding layer 930 may be formed on the fifteenth insulating interlayer 920. The fourth bonding structure 935 may be formed at a position corresponding to the third bonding structure 765. In example embodiments, the fourth bonding structure 935 may include a fourth bonding contact pattern extending through a lower portion of the fifth bonding layer 930 and an upper portion of the fifteenth insulating interlayer 920 to contact an upper surface of the thirteenth wiring 910, and a fourth bonding pad extending through an upper portion of the fifth bonding layer 930 to contact an upper surface of the fourth bonding contact pattern.

Referring to FIGS. 19 to 20 again, after turning over the sixth substrate 800, the fifth bonding layer 930 may be brought into contact with the fourth bonding layer 760, thereby bonding the sixth substrate 800 to the fifth substrate 100. The fourth bonding structure 935 may contact the third bonding structure 735. Accordingly, manufacturing of the third semiconductor device may be completed.

While the present inventive concepts have been shown and described with reference to example embodiments thereof, it will be understood by those of ordinary skill in the art that various changes in form and details may be made thereto without departing from the spirit and scope of the present inventive concepts as set forth by the following claims.

What is claimed is:

1. A semiconductor device comprising:
a transistor including:
a first gate structure on a first substrate including a first semiconductor material; and
a first channel at a portion of the first substrate below the first gate structure;
a bit line structure that extends on the transistor in a first direction substantially parallel to an upper surface of the first substrate;
a second channel including a second semiconductor material having a different crystal orientation relative to the first semiconductor material, said second channel extending on the bit line structure in a vertical direction substantially perpendicular to the upper surface of the first substrate;
a second gate structure at a first sidewall in the first direction of the second channel and extending in a second direction, which is substantially parallel to the upper surface of the first substrate and substantially perpendicular to the first direction; and
a capacitor on and electrically connected to the second channel.

2. The semiconductor device of claim 1, wherein the transistor is configured such that, when active, a direction of a current flowing in the first channel is substantially perpendicular to a {100} crystal plane, a {110} crystal plane, a {320} crystal plane, or a {310} crystal plane of the first semiconductor material; and
wherein a {100} crystal plane, a {110} crystal plane, a {320} crystal plane, or a {310} crystal plane of the second semiconductor material is substantially perpendicular to the first direction.

3. The semiconductor device of claim 1, wherein the second semiconductor material comprises a single crystal silicon, and a {100} crystal plane of the second semiconductor material is substantially perpendicular to the first direction.

4. The semiconductor device of claim 3, wherein the first semiconductor material comprises a single crystal silicon-germanium, and wherein a {110} crystal plane of the first semiconductor material is substantially perpendicular to a direction of a current flowing in the first channel when the transistor is active.

5. The semiconductor device of claim 1, further comprising:
a third gate structure at a second sidewall in the first direction of the second channel and extending in the second direction, wherein the second sidewall of the second channel facing the first sidewall of the second channel.

6. The semiconductor device of claim 1, wherein the bit line structure includes a third single crystal semiconductor material doped with impurities,
wherein the third single crystal semiconductor material and the second semiconductor material have substantially the same crystal orientation.

7. The semiconductor device of claim 1, further comprising:
a first semiconductor pattern, which extends between the bit line structure and the second channel, and includes a third semiconductor material; and
a second semiconductor pattern, which extends between the second channel and the capacitor, and includes a fourth semiconductor material.

8. The semiconductor device of claim 1, wherein the bit line structure includes a fifth semiconductor material, and wherein the second, third and fifth semiconductor materials have substantially the same crystal orientation.

9. The semiconductor device of claim 1, further comprising:
a first wiring structure on the transistor;
a bonding layer on the first wiring structure; and
a second wiring structure extending between the bonding layer and the bit line structure.

10. A semiconductor device comprising:
a first transistor on a first substrate including a first semiconductor material;
a bonding layer on the first substrate and the first transistor;
a second transistor on the bonding layer, the second transistor comprising:
a vertical channel including a second semiconductor material, said vertical channel extending in a vertical direction substantially perpendicular to an upper surface of the first substrate; and
a first gate structure at a first sidewall in a first direction of the vertical channel and extending in a second direction, each of the first and second direction substantially parallel to the upper surface of the first substrate and substantially perpendicular to each other;
a bit line structure electrically connected to the vertical channel and positioned at a first end of the vertical channel and extending in the first direction;
a capacitor electrically connected to the vertical channel, the capacitor at a second end of the vertical channel, the second end of the vertical channel facing the first end of the vertical channel, and
wherein the second semiconductor material comprises single crystal silicon, and a {100} crystal plane of the second semiconductor material is substantially perpendicular to the first direction, and
wherein the first semiconductor material comprises single crystal silicon-germanium, and a {110} crystal plane of the first semiconductor material is substantially perpendicular to a direction of a current flowing in a channel of the first transistor.

11. The semiconductor device of claim 10, further comprising:
a second gate structure at a second sidewall in the first direction of the vertical channel and extending in the second direction, the second sidewall of the vertical channel facing the first sidewall of the vertical channel.

12. The semiconductor device of claim 10, wherein the bit line structure includes a third single crystal semiconductor material doped with impurities,
wherein the third single crystal semiconductor material and the second semiconductor material have substantially the same crystal orientation.

13. The semiconductor device of claim 10, further comprising:
a first semiconductor pattern which extends between the bit line structure and the vertical channel and includes a third semiconductor material; and
a second semiconductor pattern between the vertical channel and the capacitor and includes a fourth semiconductor material.

14. The semiconductor device of claim 13, wherein the bit line structure includes a fifth semiconductor material, and wherein the second, third and fifth semiconductor materials have substantially the same crystal orientation.

15. A semiconductor device comprising:
an active pattern on a first substrate including a first semiconductor material;
a gate structure extending in a first direction substantially parallel to an upper surface of the first substrate through an upper portion of the active pattern;
a bit line structure in contact with a central portion of an upper surface of the active pattern and extending in a second direction, the second direction substantially parallel to an upper surface of the first substrate and substantially perpendicular to the first direction;
a contact plug structure in contact with each opposite edge portions of the upper surface of the active pattern;
a capacitor on the contact plug structure;
a second substrate on the capacitor and including a second semiconductor; and
a transistor below the second substrate, and
wherein the first and second semiconductor materials have different crystal orientations.

16. The semiconductor device of claim 15, wherein a {100} crystal plane, a {110} crystal plane, a {320} crystal plane, or a {310} crystal plane of the first semiconductor material is substantially perpendicular to the first direction.

17. The semiconductor device of claim 16, wherein a {100} crystal plane, a {110} crystal plane, a {320} crystal plane, or a {310} crystal plane of the second semiconductor material is substantially perpendicular to a direction of a current flowing in the transistor when the transistor is active.

18. The semiconductor device of claim 15, wherein the first semiconductor material comprises a single crystal silicon, and wherein a {100} crystal plane of the first semiconductor material is substantially perpendicular to the first direction.

19. The semiconductor device of claim 18, wherein the second semiconductor material comprises a single crystal silicon-germanium, and wherein a {110} crystal plane of the first semiconductor material is substantially perpendicular to a direction of a current flowing in the transistor when the transistor is active.

20. The semiconductor device of claim 15, further comprising:
a first wiring structure on the capacitor;
a bonding layer on the first wiring structure; and
a second wiring structure extending between the bonding layer and the transistor.
